(19) United States
(12) Patent Application Publication
(10) Pub. No.: US 2025/0159926 A1
(43) Pub. Date: May 15, 2025

(54) SEMICONDUCTOR DEVICE

(71) Applicant: FUJI ELECTRIC CO., LTD., Kawasaki-shi (JP)

(72) Inventor: Takeyoshi NISHIMURA, Matsumoto-city (JP)

(73) Assignee: FUJI ELECTRIC CO., LTD., Kawasaki-shi (JP)

(21) Appl. No.: 18/899,628

(22) Filed: Sep. 27, 2024

(30) Foreign Application Priority Data
Nov. 9, 2023 (JP) 2023-191540
Mar. 21, 2024 (JP) 2024-045525

(51) Int. Cl. H01L 29/78; H01L 29/739

(52) U.S. Cl. CPC H10D 30/665; H10D 30/668; H10D 12/481

(57) ABSTRACT

A semiconductor device including an active area and a voltage blocking area provided outwardly from the active area, the semiconductor device including: a semiconductor layer having a first conductivity type and provided over the active area and the voltage blocking area; a semiconductor region having a second conductivity type and provided on a top surface side of the semiconductor layer, in an edge section on the voltage blocking area side of the active area; and a contact section provided on a top surface side of the semiconductor region, wherein the contact section includes: a first stripe portion extending in a first direction along the edge section on the voltage blocking area side of the active area in a plan view; and a plurality of first connecting portions connected to the first stripe portion and separated from each other in the first direction.

### CROSS-REFERENCE TO RELATED APPLICATION

This application claims benefit of priority under 35 USC 119 based on Japanese Patent Applications No. 2023-191540 filed on Nov. 9, 2023, and No. 2024-045525 filed on Mar. 21, 2024, the entire contents of which are incorporated by reference herein.

### BACKGROUND OF THE INVENTION

### 1. Field of the Invention

The present disclosure relates to semiconductor devices.

### 2. Description of the Related Art

JP2020-170807A discloses: a configuration in which an active edge termination section in contact with a voltage blocking area is provided in an active area, and a second p-type region and a plurality of trench contact sections are provided in the active edge termination section; a configuration in which an electric conductor embedded in a trench contact section is formed integrally with a source electrode; and a configuration in which a plug metal is embedded in in a trench contact section via a barrier metal layer.

JP2018-120990A discloses: a configuration in which an outer region is provided between a device formation area and a breakdown voltage retention area, a p⁺-type edge termination area is provided in the outer region, and a third contact recessed section for an emitter routing section is formed; and a configuration in which a p⁺-contact region with an impurity concentration higher than that of the p⁺-type edge termination area is provided along the bottom of the third contact recessed portion, an avalanche current generated in a region outside the device formation area is collected by the emitter routing section, and the avalanche current thus collected is extracted from an emitter pad via an emitter connecting section.

JP2019-521529A discloses a configuration in which a fourth doped region is formed to have an impurity concentration of 2×10¹³ cm⁻³ to 5×10¹³ cm⁻³ and a depth of 2 μm to 4 μm, and a sixth doped region is formed to have an impurity concentration of 1×10¹⁵ cm⁻³ to 5×10¹⁵ cm³ and a depth of 0.5 μm to 1.5 μm.

The configuration in which carriers are extracted by a contact section provided in an edge section in contact with the voltage blocking area of the active area as described in JP2020-170807A and JP2018-120990A has such a problem that a current concentrates on the outer side of the contact section and it is difficult to improve a tolerance.

### SUMMARY OF THE INVENTION

An object of this disclosure is to provide a semiconductor device that allows easy extraction of carriers by a contact section in an edge section of an active area and improves a tolerance.

An aspect of the present disclosure inheres in a semiconductor device including an active area and a voltage blocking area provided outwardly from the active area, the semiconductor device including: a semiconductor layer having a first conductivity type and provided over the active area and the voltage blocking area; a semiconductor region having a second conductivity type and provided on a top surface side of the semiconductor layer, in an edge section on the voltage blocking area side of the active area; and a contact section provided on a top surface side of the first semiconductor region, wherein the contact section includes a first stripe portion extending in a first direction along the edge section on the voltage blocking area side of the active area in a plan view, and a plurality of first connecting portions connected to the first stripe portion and separated from each other in the first direction.

### BRIEF DESCRIPTION OF THE DRAWINGS

FIG. 1 is a plan view of a semiconductor device according to a first embodiment;

FIG. 2 is a plan view of the semiconductor device according to the first embodiment and illustrates a region A in FIG. 1 in an expanded manner;

FIG. 3 is a sectional view of the semiconductor device according to the first embodiment taken along a line A-A′ in FIG. 2;

FIG. 4 is a sectional view of the semiconductor device according to the first embodiment taken along a line B-B′ in FIG. 2;

FIG. 5 is a sectional view of the semiconductor device according to the first embodiment taken along a line C-C′ in FIG. 2;

FIG. 6 is a plan view of the semiconductor device according to the first embodiment and illustrates a region D in FIG. 2 in an expanded manner;

FIG. 7 is a sectional view of the semiconductor device according to the first embodiment taken along a line A-A′ in FIG. 6;

FIG. 8 is a sectional view of the semiconductor device according to the first embodiment taken along a line B-B′ in FIG. 6;

FIG. 9 is a plan view of a part of a semiconductor device according to a first comparative example;

FIG. 10 is a perspective view of the semiconductor device according to the first comparative example and corresponds to FIG. 9;

FIG. 11 is a plan view of a part of a semiconductor device according to a second comparative example;

FIG. 12 is a perspective view of the semiconductor device according to the second comparative example and corresponds to FIG. 11;

FIG. 13 is a perspective view of the semiconductor device according to the first embodiment and corresponds to FIG. 6;

FIG. 14 is a plan view of a part of a semiconductor device according to a second embodiment;

FIG. 15 is a sectional view of the semiconductor device according to the second embodiment taken along a line A-A′ in FIG. 14;

FIG. 16 is a plan view of a part of a semiconductor device according to a third embodiment;

FIG. 17 is a sectional view of the semiconductor device according to the third embodiment taken along a line A-A′ in FIG. 16;

FIG. 18 is a plan view of a part of a semiconductor device according to a fourth embodiment;

FIG. 19 is a plan view of a part of a semiconductor device according to a fifth embodiment;

FIG. 20 is a plan view of the semiconductor device according to the fifth embodiment and illustrates a region A in FIG. 19 in an expanded manner;

FIG. 21 is a sectional view of the semiconductor device according to the fifth embodiment taken along a line A-A′ in FIG. 20;

FIG. 22 is a plan view of a part of a semiconductor device according to a sixth embodiment;

FIG. 23 is a sectional view of a part of a semiconductor device according to a seventh embodiment;

FIG. 24 is a sectional view of another part of the semiconductor device according to the seventh embodiment;

FIG. 25 is a sectional view of a part of a semiconductor device according to an eighth embodiment;

FIG. 26A is an illustration of the reverse recovery property of a diode;

FIG. 26B is a graph illustrating the relationship between a dose in a contact region and the rate of change of a reverse recovery current of a semiconductor device according to a ninth embodiment;

FIG. 27 is a plan view of a part of a semiconductor device according to a tenth embodiment;

FIG. 28 is a sectional view taken along a line A-A′ in FIG. 27;

FIG. 29 is a sectional view taken along a line B-B′ in FIG. 27;

FIG. 30A is a sectional view taken along a line C-C′ in FIG. 27;

FIG. 30B is a sectional view taken along a line D-D′ in FIG. 27;

FIG. 31 is a sectional view of a part of a semiconductor device according to an eleventh embodiment;

FIG. 32 is a sectional view of another part of the semiconductor device according to the eleventh embodiment;

FIG. 33 is a sectional view of a part of a semiconductor device according to a twelfth embodiment;

FIG. 34 is a sectional view of another part of the semiconductor device according to the twelfth embodiment;

FIG. 35 is a sectional view of a part of a semiconductor device according to a thirteenth embodiment;

FIG. 36 is a sectional view of another part of the semiconductor device according to the thirteenth embodiment;

FIG. 37 is a sectional view of a part of a semiconductor device according to a fourteenth embodiment;

FIG. 38 is a sectional view of a part of a semiconductor device according to a fifteenth embodiment;

FIG. 39 is a sectional view of a part of a semiconductor device according to a sixteenth embodiment; and

FIG. 40 is a sectional view of a part of a semiconductor device according to a seventeenth embodiment.

### DETAILED DESCRIPTION

With reference to the drawings, first to seventeenth embodiments of the present disclosure will be described below.

In the drawings, the same or similar elements are indicated by the same or similar reference numerals.

The drawings are schematic, and it should be noted that the relationship between thickness and planer dimensions, the thickness proportion of each layer, and the like are different from real ones. Accordingly, specific thicknesses or dimensions should be determined with reference to the following description. Moreover, in some drawings, portions are illustrated with different dimensional relationships and proportions.

In the following description, a “first main electrode region” and a “second main electrode region” are a main electrode region of a semiconductor element, in which a main current flows in or out. The first main electrode region is assigned to a semiconductor region which is a source region or a drain region in a field-effect transistor (FET) or a static induction transistor (SIT). The first main electrode region is assigned to a semiconductor region which is an emitter region or a collector region in an insulated gate bipolar transistor (IGBT). The first main electrode region is assigned to a semiconductor region which is an anode region or a cathode region in a static induction (SI) thyristor or a gate turn-off (GTO) thyristor. The second main electrode region is assigned to a semiconductor region which is not assigned as the first main electrode region and will be the source region or the drain region in the FET or the SIT, the emitter region or the collector region in the IGBT, and the anode region or the cathode region in the SI thyristor or the GTO thyristor. That is, when the first main electrode region is the source region, the second main electrode region means the drain region. When the first main electrode region is the emitter region, the second main electrode region means the collector region. When the first main electrode region is the anode region, the second main electrode region means the cathode region. A “main electrode region” is described in the specification, the main electrode region comprehensively means any one of the first main electrode region and the second main electrode region.

Further, definitions of directions such as an up-and-down direction in the following description are merely definitions for convenience of understanding, and are not intended to limit the technical ideas of the present disclosure. For example, as a matter of course, when the subject is observed while being rotated by 90°, the subject is understood by converting the up-and-down direction into the right-and-left direction. When the subject is observed while being rotated by 180°, the subject is understood by inverting the up-and-down direction. In addition, a “top surface” may be read as “front surface”, and a “bottom surface” may be read as “back surface”.

Further, in the following description, there is exemplified a case where a first conductivity type is an n-type and a second conductivity type is a p-type. However, the relationship of the conductivity types may be inverted to set the first conductivity type to the p-type and the second conductivity type to the n-type. Further, a semiconductor region denoted by the symbol “n” or “p” attached with “+” indicates that such semiconductor region has a relatively high impurity concentration or a relatively low specific resistance as compared to a semiconductor region denoted by the symbol “n” or “p” without “+”. A semiconductor region denoted by the symbol “n” or “p” attached with “−” indicates that such semiconductor region has a relatively low impurity concentration or a relatively high specific resistance as compared to a semiconductor region denoted by the symbol “n” or “p” without “−”. However, even when the semiconductor regions are denoted by the same reference symbols “n” and “n”, it is not indicated that the semiconductor regions have exactly the same impurity concentration or the same specific resistance.

### DETAILED DESCRIPTION

### First Embodiment

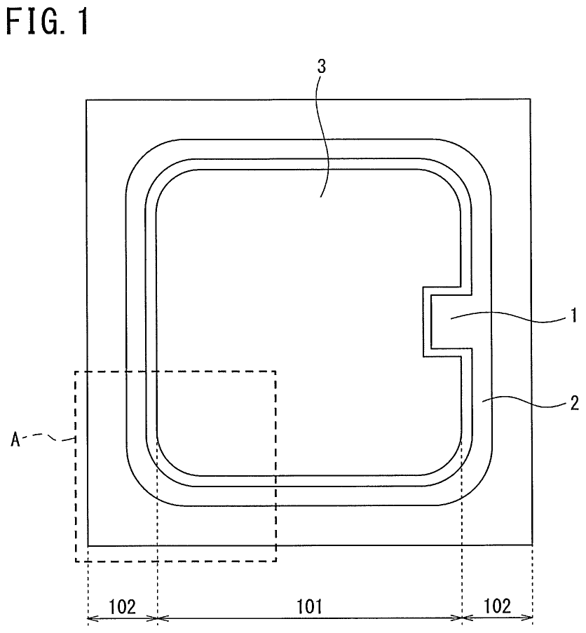

FIG. 1 is a plan view of a semiconductor device according to a first embodiment. As illustrated in FIG. 1, the semiconductor device according to the first embodiment has a generally rectangular planar shape. The semiconductor device according to the first embodiment includes an active area 101 provided on an inner side of the semiconductor device according to the first embodiment, and a voltage blocking area (an edge termination area) 102 provided outside the active area 101 to surround the active area 101.

The active area 101 has a generally rectangular planar shape. The active area 101 is a region which includes an active element (a switching element) and through which a main current flows when the active element is turned on. The active element may be a vertical switching element, for example. The semiconductor device according to the first embodiment deals with a case where the active element included in the active area 101 is a MOSFET having a planar gate structure. The active area 101 includes a surface electrode (source electrode) 3.

The voltage blocking area 102 has an annular (frame-shaped) planar shape to surround the active area 101. The voltage blocking area 102 is a region that relaxes an electric field and maintains a breakdown voltage.

A gate pad 1 is provided partially between the active area 101 and the voltage blocking area 102. The gate pad 1 has a generally rectangular planar shape. A wiring layer (gate runner) 2 is electrically connected to the gate pad 1. The gate runner 2 is provided in the voltage blocking area 102 to surround the active area 101. The gate pad 1 is electrically connected to a gate electrode of the active element in the active area 101 via the gate runner 2.

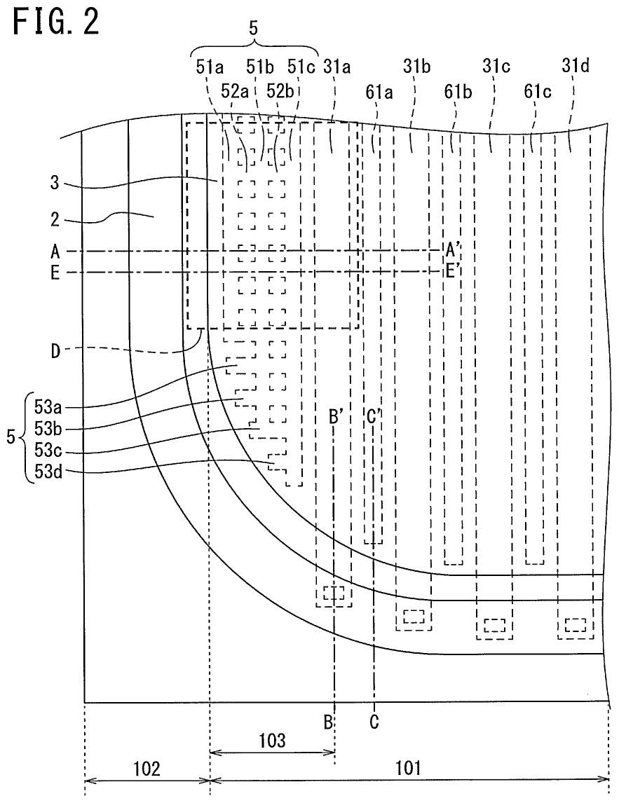

FIG. 2 is a plan view illustrating, in an enlarged manner, a region A including a rectangular corner (corner portion) formed in the planar shape of the semiconductor device according to the first embodiment illustrated in FIG. 1. As illustrated in FIG. 2, the active area 101 includes gate electrodes 31a to 31d of the MOSFET as the active element, and contact sections (plug sections) 61a to 61c sandwiched between the gate electrodes 31a to 31d. In the semiconductor device according to the first embodiment, the contact sections 61a to 61c are trench contact sections at least partially embedded in respective trenches provided on the top surface side of the semiconductor device according to the first embodiment. The gate electrodes 31a to 31d and the trench contact sections 61a to 61c have a linear (stripe-shaped) planar shape extending in one direction (the up-down direction in FIG. 2) to be parallel to each other. Here, in a plan view of the semiconductor device according to the first embodiment, the extending direction (the up-down direction in FIG. 2) of the gate electrodes 31a to 31d and the trench contact sections 61a to 61c is defined as a “first direction,” and a direction (the right-left direction in FIG. 2) perpendicular to the extending direction of the gate electrodes 31a to 31d and the trench contact sections 61a to 61c is defined as a “second direction.”

An edge section (active edge termination section) 103 on the voltage blocking area 102 side of the active area 101 is provided with a contact section (a plug section) 5. In the semiconductor device according to the first embodiment, the contact section 5 is a trench contact section at least partially embedded in a trench provided on the top surface side of the semiconductor device according to the first embodiment. The active edge termination section 103 is provided inside the source electrode 3 in a plan view. In FIG. 2, the gate electrodes 31a to 31d, the trench contact sections 61a to 61c, and the trench contact section 5, which are hidden under a bottom surface side of the source electrode 3, are schematically indicated by a broken line.

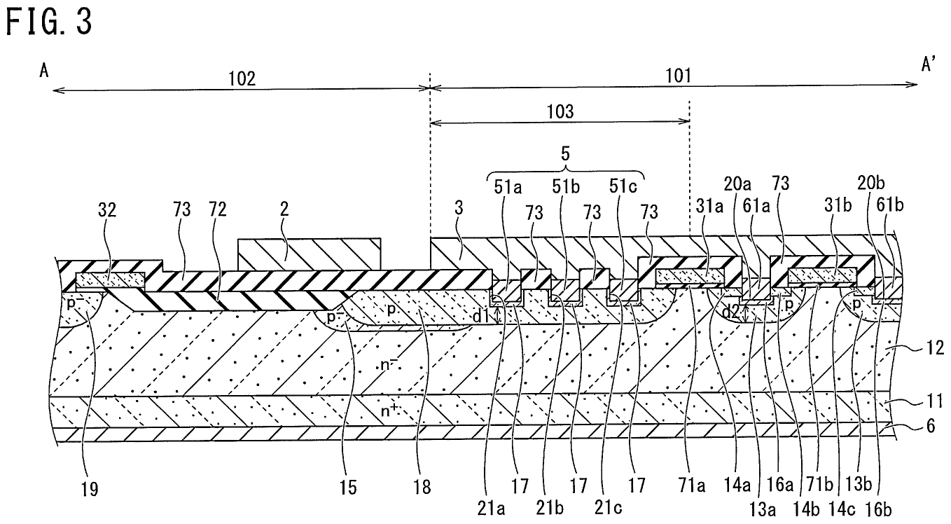

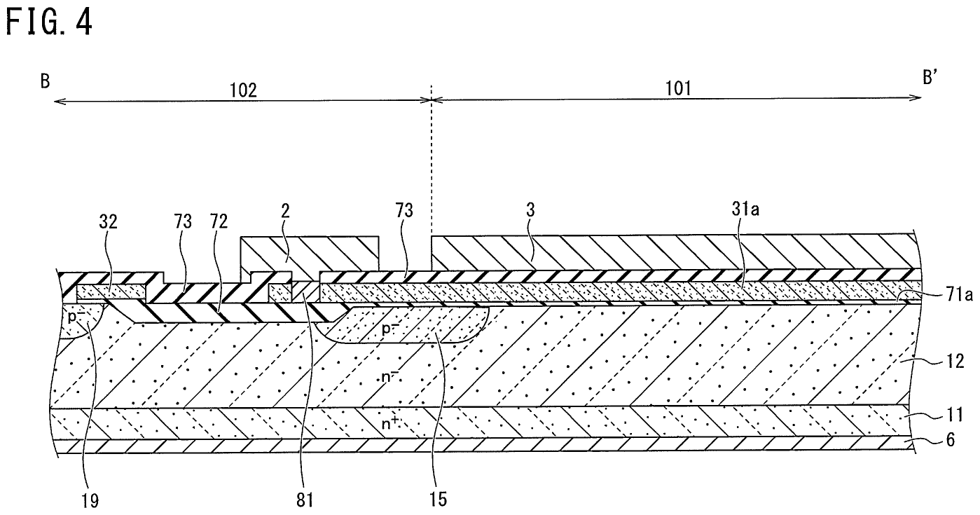

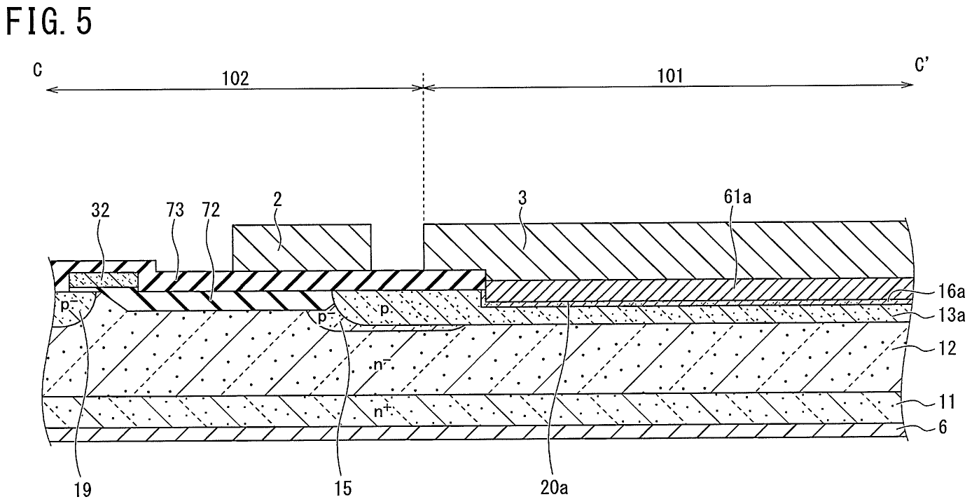

FIG. 3 is a section view taken along a line A-A′ in FIG. 2, FIG. 4 is a section view taken along a line B-B′ in FIG. 2, and FIG. 5 is a section view taken along a line C-C′ in FIG. 2. As illustrated in FIG. 3 to FIG. 5, the semiconductor device according to the first embodiment includes a main electrode region (drain region) 11 having a first conductivity type (n⁺-type) and provided over the active area 101 and the voltage blocking area 102, and an n-type semiconductor layer (drift layer) 12 provided on the top surface side of the drain region 11 and having an impurity concentration lower than that of the drain region 11.

The drain region 11 is constituted by a semiconductor substrate such as a silicon (Si) substrate. The semiconductor substrate constituting the drain region 11 is not limited to the Si substrate and may be, for example, a semiconductor substrate made of a wideband gap semiconductor such as silicon carbide (SiC), gallium nitride (GaN), gallium oxide (Ga₂O₃), diamond (C), or aluminum nitride (AlN).

The drift layer 12 is constituted by an epitaxially-grown layer made of Si. Note that the drift layer 12 may be constituted by an n-type semiconductor substrate, and the n⁺-type drain region 11 may be formed on the bottom surface side of the semiconductor substrate by ion implantation or thermal diffusion.

In the active area 101, semiconductor regions (base regions) 13a, 13b having a second conductivity type (p-type) are provided in contact with the drift layer 12 on the top surface side of the drift layer 12. A parasitic diode is formed by the base regions 13a, 13b and the drift layer 12. Further, n⁺-type main electrode regions (source regions) 14a and 14b are provided in contact with the base region 13a on the top surface side of the base region 13a. An n⁺-type source region 14c is provided in contact with the base region 13b on the top surface side of the base region 13b.

The gate electrode 31a is provided on respective top surface sides of the drift layer 12 and the base region 13a via a gate insulating film 71a. An insulated-gate electrode structure (31a, 71a) is constituted by the gate insulating film 71a and the gate electrode 31a. The gate electrode 31b is provided on respective top surface sides of the drift layer 12 and the base region 13b via a gate insulating film 71b. An insulated-gate electrode structure (31b, 71b) is constituted by the gate insulating film 71b and the gate electrode 31b.

As the gate insulating films 71a, 71b, a single layer film selected from a silicon oxide film (SiO₂ film), an silicon oxynitride (SiON) film, a strontium oxide (SrO) film, a silicon nitride (Si₃N₄) film, an aluminum oxide (Al₂O₃) film, a magnesium oxide (MgO) film, a yttrium oxide (Y₂O₃) film, a hafnium oxide (HfO₂) film, a zirconium oxide (ZrO₂) film, a tantalum oxide (Ta₂O₅) film, and a bismuth oxide (Bi₂O₃) film, a composite film obtained by stacking a plurality of films selected therefrom, or the like can be employed, for example.

As a material for the gate electrodes 31a, 31b, a polysilicon film (a doped polysilicon film) to which an n-type impurity such as phosphor (P) or arsenic (As) or a p-type impurity such as boron (B) is doped at a high impurity concentration is usable, for example.

An interlayer insulating film 73 is provided on respective top surfaces of the drift layer 12 and the insulated-gate electrode structures (31a, 71a), (31b, 71b). The interlayer insulating film 73 is constituted by, for example, a single layer film such as a non-doped silicon oxide film (SiO₂ film) called a non-doped silicate glass (NSG) and not including phosphor (P) or boron (B), a high-temperature oxide film (HTO film), a silicon nitride film (Si₃N₄ film), a phosphosilicate glass film (PSG film) to which phosphor is doped, a borosilicate glass film (BSG film) to which boron is doped, or a borophosphosilicate glass film (BPSG film) to which boron and phosphorus are doped, or a stacked-layer film of these films.

The interlayer insulating film 73 has contact holes passing through the interlayer insulating film 73. The epitaxially-grown layer constituting the drift layer 12 has trenches (contact trenches) 20a, 20b continuous with the contact holes in the interlayer insulating film 73. The contact trenches 20a, 20b are provided in a depth direction that is a vertical direction to the top surface of the epitaxially-grown layer constituting the drift layer 12.

A side surface on the left side of the contact trench 20a makes contact with the source region 14a, and a side surface on the right side of the contact trench 20a makes contact with the source region 14b. A p⁺-type contact region 16a is provided in contact with the contact trench 20a, in a bottom portion of the contact trench 20a. The contact region 16a makes contact with the base region 13a. The impurity concentration of the contact region 16a is higher than the impurity concentration of the base region 13a. A side surface on the left side of the contact trench 20b makes contact with the source region 14c. A p⁺-type contact region 16b is provided in contact with the contact trench 20b, in a bottom portion of the contact trench 20b. The contact region 16b makes contact with the base region 13b. The impurity concentration of the contact region 16b is higher than the impurity concentration of the base region 13b.

The trench contact section (the plug section) 61a, 61b is at least partially embedded in the contact trench 20a, 20b. The trench contact section 61a, 61b includes a barrier metal film provided in contact with the contact trench 20a, 20b, and a contact plug embedded in the contact trench 20a, 20b via the barrier metal film. As the barrier metal film, a single layer film such as titanium (Ti) or titanium nitride (TiN), a stacked-layer film of Ti and TiN, and the like are usable, for example. As the contact plug, metal made of refractory metal such as tungsten (W) is usable.

The source electrode 3 is provided on the interlayer insulating film 73. As the source electrode 3, metal such as aluminum (Al), Al alloy, or copper (Cu) is usable. The Al alloy can be Al-silicon (Si), Al—Si-copper (Cu), Al—Cu, and the like. The source electrode 3 is electrically connected to the source regions 14a to 14c and the contact regions 16a, 16b via the trench contact sections 61a, 61b.

A back-surface electrode (drain electrode) 6 is provided on the bottom surface of the drain region 11. The drain electrode 6 can be constituted by a single layer made of gold (Au) or a metal film including titanium (Ti), nickel (Ni), and gold (Au) stacked in this order, for example.

At the time of the operation of the MOSFET as the active element included in the active area 101 of the semiconductor device according to the first embodiment, a positive voltage is applied to the drain electrode 6 with the source electrode 3 being as a ground potential, and a positive voltage equal to or more than a threshold is applied to the gate electrodes 31a, 31b, so that inversion layers (channels) are formed in the base regions 13a, 13b, and the MOSFET is brought into an ON state. In the ON state, a current flows from the drain electrode 6 to the source electrode 3 via the drain region 11, the drift layer 12, the inversion layers of the base regions 13a, 13b, and the source regions 14a to 14c. In the meantime, in a case where the voltage applied to the gate electrodes 31a, 31b is less than the threshold, no inversion layer is formed in the base regions 13a, 13b, so that the MOSFET is brought into an OFF state, and no current flows from the drain electrode 6 to the source electrode 3.

In the active edge termination section 103 provided in the edge section on the voltage blocking area 102 side of the active area 101, a p-type semiconductor region (well region) 18 is provided on the top surface side of the drift layer 12 in such a manner as to be separated from the base region 13a of the active area 101. The well region 18 is formed in the same process as the base regions 13a, 13b of the active area 101. The depth of the well region 18 is generally the same as the depth of the base regions 13a, 13b of the active area 101 and is about 1 μm or more but 2 μm or less, for example.

Trenches (contact trenches) 21a to 21c are provided in an upper portion of the well region 18. The contact trenches 21a to 21c are formed in the same process as the contact trenches 20a, 20b of the active area 101. The depth of the contact trenches 21a to 21c is generally the same as the depth of the contact trenches 20a, 20b of the active area 101 and is, for example, about 0.4 μm or more but 0.8 μm or less.

Respective contact regions 17 as p⁺-type highly-concentrated low-resistance regions are provided in contact with the contact trenches 21a to 21c, on respective side surface sides and bottom surface sides of the contact trenches 21a to 21c. The contact regions 17 make contact with the well region 18. The impurity concentration of the contact regions 17 is higher than the impurity concentration of the well region 18. The contact region 17 is formed in the same process as the contact regions 16a, 16b of the active area 101. The impurity concentration of the contact regions 17 is generally the same as the impurity concentration of the contact regions 16a, 16b of the active area 101. The depth of the contact regions 17 is generally the same as the depth of the contact regions 16a, 16b of the active area 101.

The trench contact section (the plug section) 5 is at least partially embedded in the contact trenches 21a to 21c. The trench contact section 5 is formed in the same process as the trench contact sections 61a, 61b of the active area 101 and is made of the same material as the trench contact sections 61a, 61b of the active area 101. The trench contact section 5 includes a barrier metal film provided in contact with the contact trenches 21a to 21c, and a contact plug embedded in the contact trenches 21a to 21c via the barrier metal film and made of refractory metal such as W. The trench contact section 5 is electrically connected to the source electrode 3.

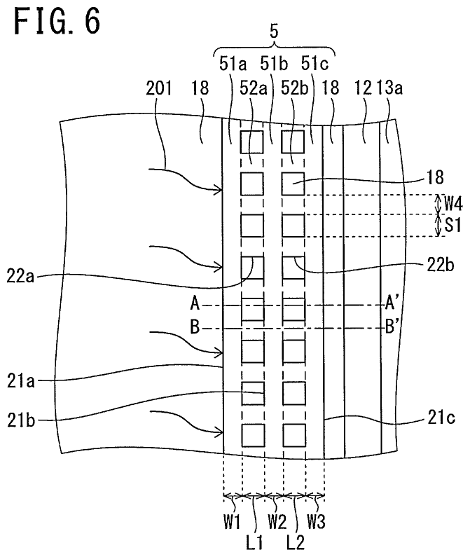

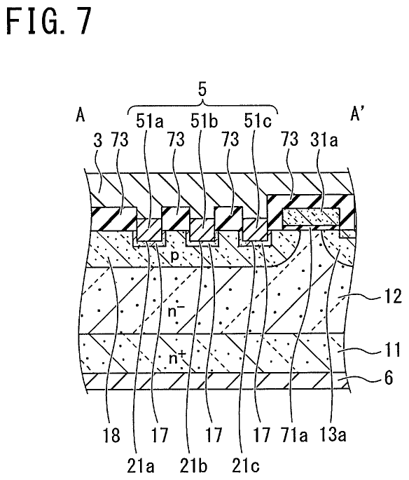

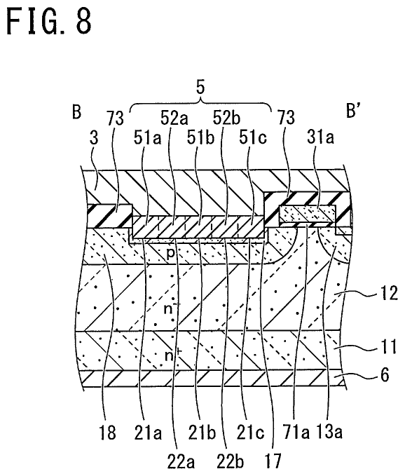

FIG. 6 is a plan view illustrating, in an enlarged manner, a region D including part of the trench contact section 5 in the active edge termination section 103 illustrated in FIG. 2. In FIG. 6, the source electrode 3, the interlayer insulating film 73, the gate electrode 31a, and the gate insulating film 71a are omitted. In FIG. 6, the flow of carriers at the time of a switching operation of the semiconductor device according to the first embodiment is schematically indicated by an arrow 201. FIG. 7 is a section view taken along a line A-A′ in FIG. 6, and FIG. 8 is a section view taken along a line B-B′ in FIG. 6.

As illustrated in FIG. 6 to FIG. 8, the trench contact section 5 has a lattice-shaped planar shape. The trench contact section 5 includes a plurality of (three) stripe portions 51a to 51c extending linearly (in a stripe shape) in the first direction (the up-down direction in FIG. 6), a plurality of connecting portions 52a provided between the stripe portions 51a, 51b and separated from each other in the first direction, and a plurality of connecting portions 52b provided between the stripe portions 51b, 51c and separated from each other in the first direction.

The stripe portions 51a to 51c are embedded in the contact trenches 21a to 21c, respectively. Respective widths W1 to W3 of the stripe portions 51a to 51c in the second direction (the left-right direction in FIG. 6) are, for example, about 0.3 μm or more but 1 μm or less. The widths W1 to W3 of the stripe portions 51a to 51c may be equal to each other or may be different from each other.

The plurality of connecting portions 52a is embedded in a contact trench 22a. The plurality of connecting portions 52a has a generally rectangular planar shape. One end, in the second direction, of each of the plurality of connecting portions 52a is connected to the stripe portion 51a, and the other end, in the second direction, of each of the plurality of connecting portions 52a is connected to the stripe portion 51b. A length L1 of the plurality of connecting portions 52a in the second direction is about 0.3 μm or more but 1 μm or less, for example.

The plurality of connecting portions 52b is embedded in a contact trench 22b. One end, in the second direction, of each of the plurality of connecting portions 52b is connected to the stripe portion 51b, and the other end, in the second direction, of each of the plurality of connecting portions 52b is connected to the stripe portion 51c. A length L2 of the plurality of connecting portions 52b in the second direction is about 0.3 μm or more but 1 μm or less, for example. The length L2 of the plurality of connecting portions 52b in the second direction may be the same as or different from the length L1 of the plurality of connecting portions 52a in the second direction.

The plurality of connecting portion 52a and the plurality of connecting portions 52b are provided at the same pitch in the first direction. A width W4, in the first direction, of the plurality of connecting portions 52a and the plurality of connecting portions 52b is, for example, about 0.3 μm or more but 1 μm or less. The width W4, in the first direction, of the plurality of connecting portions 52a and the plurality of connecting portions 52b may be the same as the length L1 of the plurality of connecting portions 52a in the second direction or the length L2 of the plurality of connecting portions 52b in the second direction, or may be larger or smaller than the length L1 of the plurality of connecting portions 52a in the second direction or the length L2 of the plurality of connecting portions 52b in the second direction.

An interval S1, in the first direction, between the plurality of connecting portions 52a and between the plurality of connecting portions 52b is, for example, about 0.3 μm or more but 1 μm or less. The interval S1, in the first direction, between the plurality of connecting portions 52a and between the plurality of connecting portions 52b may be the same as the width W4, in the first direction, of the plurality of connecting portions 52a and the plurality of connecting portions 52b or may be larger or smaller than the width W4, in the first direction, of the plurality of connecting portions 52a and the plurality of connecting portions 52b. The number of the plurality of connecting portions 52a and the number of the plurality of connecting portions 52b are not particularly limited.

Note that the lattice-shaped planar shape of the trench contact section 5 can be regarded as a planar shape in which the plurality of (three) stripe portions 51a to 51c extending linearly (in a stripe shape) in the first direction intersects with a plurality of stripe portions extending linearly (in a stripe shape) in the second direction so as to continuously include the plurality of connecting portions 52a and the plurality of connecting portion 52b.

As illustrated in FIG. 2, in a rectangular corner (corner portion) formed in the planar shape of the active area 101, a corner (corner portion) of the active area 101 has a curved shape, and a corner (corner portion) of the source electrode 3 also has a curved shape. The lengths of the stripe portions 51a to 51c of the trench contact section 5 in the active edge termination section 103 vary along the curved shape of the corner of the active area 101. The length, in the first direction, of the outermost stripe portion 51a is shorter than the length, in the first direction, of the stripe portion 51b provided inwardly from the stripe portion 51a. The length, in the first direction, of the stripe portion 51b is shorter than the length, in the first direction, of the stripe portion 51c provided inwardly from the stripe portion 51b.

The trench contact section 5 in the active edge termination section 103 further includes a plurality of connecting portions 53a to 53d in the corner of the active area 101. One end, in the second direction, of each of the plurality of connecting portions 53a to 53c is connected to the stripe portion 51b. Respective lengths, in the second direction, of the connecting portions 53a to 53c vary along the curved shape of the corner of the active area 101. The lengths, in the second direction, of the connecting portions 53a to 53c become short toward the corner of the active area 101. One end, in the second direction, of the connecting portion 53d is connected to the stripe portion 51c.

At the time when the semiconductor device according to the first embodiment is turned off, a depletion layer is formed in the active edge termination section 103 due to a p-n junction between the p-type well region 18 and the n⁻-type drift layer 12, and carriers are accumulated in the depletion layer. At the time when the semiconductor device according to the first embodiment is turned on, the carriers thus accumulated in the depletion layer flow from the voltage blocking area 102 side toward the active area 101 side as indicated by the arrow 201 in FIG. 6 and are extracted by the source electrode 3 via the trench contact section 5.

As illustrated in FIG. 3 to FIG. 5, in the voltage blocking area 102, the p-type well region 18 is provided on the top surface side of the drift layer 12 in such a manner as to be continuous with the active area 101. A p-type semiconductor region (resurf region) 15 having an impurity concentration lower than that of the well region 18 is provided on the top surface side of the drift layer 12 in such a manner as to cover a bottom surface and a side surface of the outer side of the well region 18. The gate runner 2 is provided on the top surface sides of the well region 18 and the resurf region 15 via a field insulating film 72 made of a local oxide film (a LOCOS film) or the like and the interlayer insulating film 73. A p-type semiconductor region (channel stopper) 19 is provided in a chip edge portion that is an outermost periphery of the voltage blocking area 102. A field plate 32 made of polysilicon is provided on the top surface side of the channel stopper 19 via the interlayer insulating film 73.

In the semiconductor device according to the first embodiment, the on-resistance (on-state voltage) of the active element itself included in the active area 101 decreases along with improvement in design and machining accuracy due to microfabrication or the like, but a tolerance tends to decrease due to an increase in current density. In order to improve the tolerance, at the time of forming a contact in the active area 101, the contact trenches 20a, 20b are formed such that the semiconductor layer is dug down to a region deeper than the source regions 14a to 14c, and the trench contact sections (the plug sections) 61a, 61b are embedded in the contact trenches 20a, 20b. Hereby, carriers are directly extracted from a parasitic diode region formed by the p-type base regions 13a, 13b and the n-type drift layer 12, thereby restraining a parasitic transistor operation. At this time, refractory metal is embedded and flattened in the contact trenches 20a, 20b so that an increase in resistance is reduced even with a small contact area.

Further, the active element included in the active area 101 is formed as a stripe-shaped cell (stripe cell) including the gate electrodes 31a, 31b extending in a stripe shape, thereby making it possible to achieve uniformity in the cell and increase a breakdown voltage and an on-resistance (on-state voltage) performance index. In a case where the active element included in the active area 101 is a stripe cell, it is general to form a contact in parallel to the stripe cell in the active edge termination section 103 provided in the edge section on the voltage blocking area 102 side of the active area 101. At this time, it is preferable that the contact of the active edge termination section 103 have a large contact area so as to achieve excellent extraction of a current at the time of switching or the like. Further, in order to improve a tolerance, the semiconductor layer is dug down to form the contact trenches 21a to 21c, 22a, 22b, and the trench contact section 5 is embedded in the contact trenches 21a to 21c, 22a, 22b. Hereby, carriers are directly extracted from a parasitic diode region formed by the p-type well region 18 and the p-type resurf region 15 with the n⁻-type drift layer 12, thereby making it possible to restrain a parasitic transistor operation.

### First Comparative Example

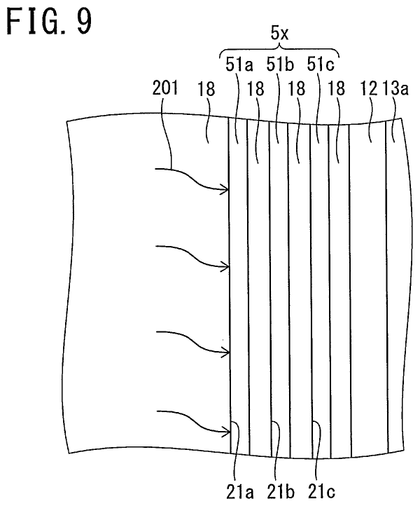

FIG. 9 is a plan view of a part of a semiconductor device according to a first comparative example and corresponds to the plan view of the semiconductor device according to the first embodiment illustrated in FIG. 6. As illustrated in FIG. 9, the semiconductor device according to the first comparative example is different from the semiconductor device according to the first embodiment illustrated in FIG. 6 in that a trench contact section 5x is constituted by only three stripe portions 51a to 51c extending in the first direction (the up-down direction in FIG. 9). The stripe portions 51a to 51c are embedded in the contact trenches 21a to 21c, respectively. In the case of the semiconductor device according to the first comparative example, it is necessary to fill the contact trenches 21a to 21c with refractory metal, so that the contact trenches 21a to 21c have narrow widths, and in order to increase respective contact areas, a plurality of stripe-shaped contact trenches 21a to 21c is arranged side by side.

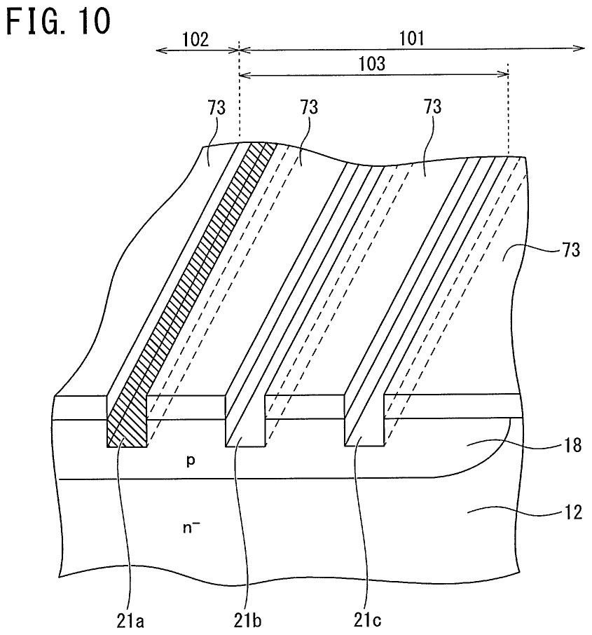

FIG. 10 is a perspective view of the semiconductor device according to the first comparative example and corresponds to FIG. 9. In FIG. 10, the stripe portions 51a to 51c embedded in the contact trenches 21a to 21c are omitted, and respective side surfaces and respective bottom surfaces of the contact trenches 21a to 21c are exposed. In FIG. 10, in the contact trenches 21a to 21c, a place with a relatively large extraction amount of carriers is schematically illustrated with oblique hatching.

As illustrated in FIG. 10, in the case of the semiconductor device according to the first comparative example, a drawing current concentrates on an outer side surface and the bottom surface of the outermost contact trench 21a among the contact trenches 21a to 21c, so that the outer side surface and the bottom surface of the contact trench 21a have a relatively large extraction amount of carriers. In the meantime, an inner side surface of the contact trench 21a and respective outer and inner side surfaces and respective bottom surfaces of the contact trenches 21b, 21c provided inwardly from the contact trench 21a have a relatively small extraction amount of carriers. Thus, in comparison with the whole contact area of the contact trenches 21a to 21c, a contact area where carriers are easily extracted is small, so that the improvement in tolerance cannot be expected.

### Second Comparative Example

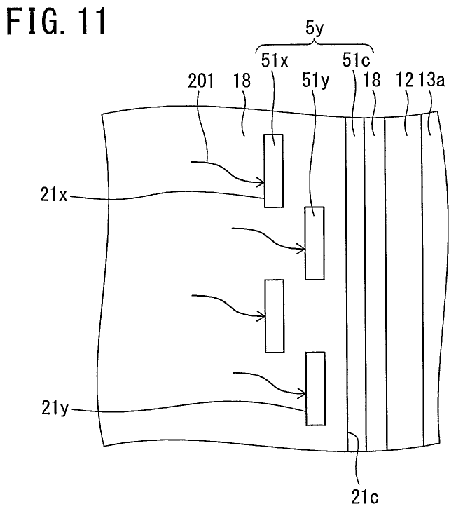

FIG. 11 is a plan view of a part of a semiconductor device according to a second comparative example and corresponds to the plan view of the semiconductor device according to the first embodiment illustrated in FIG. 6. As illustrated in FIG. 11, the semiconductor device according to the second comparative example is different from the semiconductor device according to the first embodiment illustrated in FIG. 6 in that a trench contact section 5y is constituted by a plurality of island portions 51x provided to be separated from each other in the first direction (the up-down direction in FIG. 11), a plurality of island portions 51y provided inwardly from the plurality of island portions 51x and separated from each other in the first direction, and one stripe portion 51c provided inwardly from the plurality of island portions 51y and extending in the first direction. The plurality of island portions 51x and the plurality of island portions 51y are embedded in contact trenches 21x, 21y, respectively. The stripe portion 51c is embedded in the contact trench 21c.

In the case of the semiconductor device according to the second comparative example, current concentration is relaxed by disposing the plurality of island portions 51x at positions different from those of the plurality of island portions 51y. However, the resistance of metal constituting the plurality of island portions 51x, 51y and the stripe portion 51c is lower by three digits or more than the resistance of a semiconductor, and therefore, even if the plurality of island portions 51x and the plurality of island portions 51y are separately disposed at different positions, a current flows through places with a low resistance, so that the current concentrates on the plurality of island portions 51x and the plurality of island portions 51y on the outer side, and a tolerance decreases.

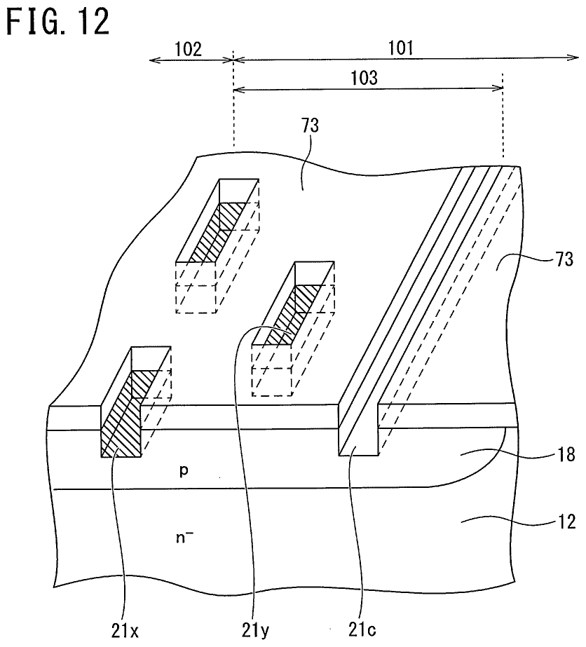

FIG. 12 is a perspective view of the semiconductor device according to the second comparative example and corresponds to FIG. 11. In FIG. 12, the plurality of island portions 51x, the plurality of island portions 51y, and the stripe portion 51c embedded in the contact trenches 21x, 21y, 21c are omitted, and respective side surfaces and respective bottom surfaces of the contact trenches 21x, 21y, 21c are exposed. In FIG. 12, in the contact trenches 21x, 21y, 21c, a place with a large extraction amount of carriers is schematically illustrated with oblique hatching.

As illustrated in FIG. 12, in the case of the semiconductor device according to the second comparative example, among the contact trenches 21x, 21y, 21c, an outer side surface, two side surfaces facing each other in the first direction, and a bottom surface in the outermost contact trench 21x, and an outer side surface, two side surfaces facing each other in the first direction, and a bottom surface in the contact trench 21y provided inwardly from the contact trench 21x and disposed at a position deviating from the contact trench 21x have a relatively large extraction amount of carriers. In the meantime, outer and inner side surfaces and a bottom surface of the contact trench 21c provided inwardly from the contact trenches 21x, 21y have a relatively small extraction amount of carriers. Accordingly, a contact area where carriers are easily extracted is small, and improvement in tolerance is insufficient.

<Effects of Semiconductor Device according to First Embodiment>

In comparison with the first and second comparative examples, the semiconductor device according to the first embodiment is configured such that the stripe portions 51a to 51c are connected to each other via the plurality of connecting portions 52a, 52b in the trench contact section 5, as illustrated in FIG. 6. Hereby, a current is easily extracted from the whole trench contact section 5 as well as the outermost stripe portion 51a, thereby preventing the current from concentrating on the outermost stripe portion 51a. For example, carriers are easily equally extracted from at least two side surfaces facing each other in the first direction and a bottom surface in each of the plurality of connecting portions 52a connected to the stripe portion 51a, and a bottom surface of the stripe portion 51b provided inwardly from the plurality of connecting portions 52a and connected to the plurality of connecting portions 52a, in addition to the outer side surface and the bottom surface of the outermost stripe portion 51a.

Further, minute contact trenches 21a to 21c, 22a, 22b can be formed at a pitch smaller than a cell pitch, and when the contact trenches 21a to 21c, 22a, 22b are arranged equally, a current is easily dispersed, so that a contact area effective to equally extract carriers can be also increased. The contact area of the trench contact section 5 in each of the semiconductor device according to the first embodiment and semiconductor devices according to second to eighth embodiments (described later) are about one to four times the contact areas of the semiconductor devices according to the first and second comparative examples, for example. However, a contact area effective to equally extract carriers in the trench contact section 5 in each of the semiconductor device according to the first embodiment and the semiconductor devices according to the second to eighth embodiments (described later) is larger than the contact areas of the semiconductor devices according to the first and second comparative examples and can be around two or more times the contact areas of the semiconductor devices according to the first and second comparative examples, for example.

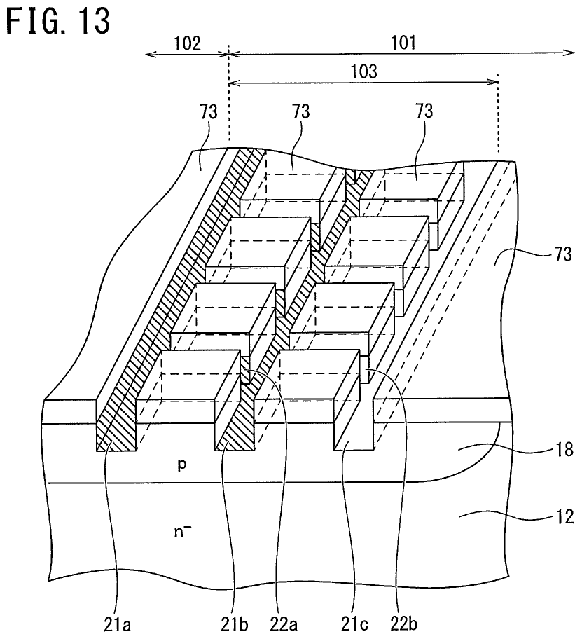

FIG. 13 is a perspective view of the semiconductor device according to the first embodiment and corresponds to FIG. 6. In FIG. 13, the stripe portions 51a to 51c embedded in the contact trenches 21a to 21c and the plurality of connecting portions 52a, 52b embedded in the contact trenches 22a, 22b are omitted, and respective side surfaces and respective bottom surfaces of the contact trenches 21a to 21c, 22a, 22b are exposed. In FIG. 13, in the contact trenches 21a to 21c, 22a, 22b, a place with a relatively large extraction amount of carriers is schematically illustrated with oblique hatching.

As illustrated in FIG. 13, the semiconductor device according to the first embodiment is configured such that the stripe-shaped contact trenches 21a to 21c are connected to each other via the contact trenches 22a, 22b. Hereby, carriers are easily equally extracted from two side surfaces facing each other in the first direction and the bottom surface in the contact trench 22a connected to the contact trench 21a, the bottom surface of the contact trench 21b connected to the contact trench 22a, and so on, in addition to the outer side surface and the bottom surface of the outermost contact trench 21a. This makes it possible to increase a contact area effective to equally extract carriers, thereby making it possible to improve a tolerance.

In addition, in the case of the semiconductor device according to the first embodiment, in the rectangular corner (corner portion) formed in the planar shape of the active area 101, the active edge termination section 103 includes the plurality of connecting portions 53a to 53d having a shape along the curved shape of the corner of the active area 101, as illustrated in FIG. 2. Accordingly, carriers are easily equally extracted even from the corner of the active area 101.

### Second Embodiment

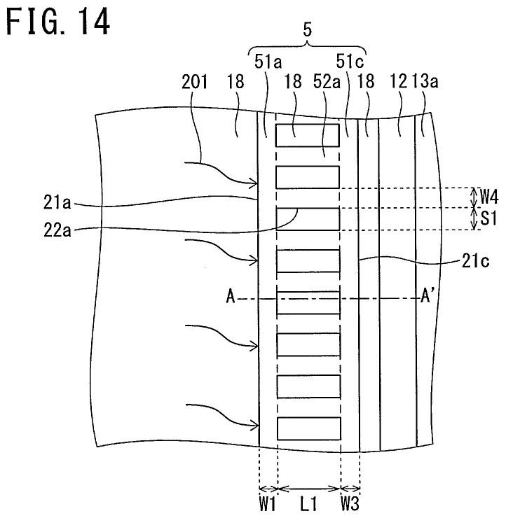

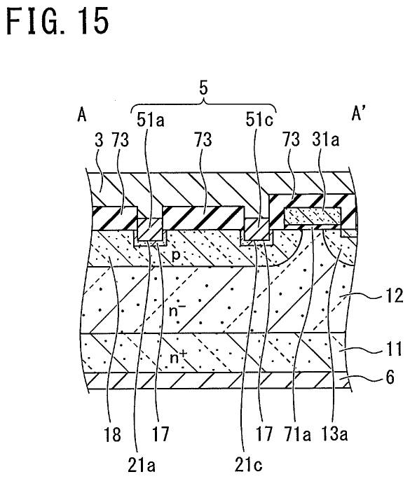

FIG. 14 is a plan view of a part of a semiconductor device according to a second embodiment and corresponds to the plan view of the semiconductor device according to the first embodiment illustrated in FIG. 6. FIG. 15 is a sectional view taken along a line A-A′ in FIG. 14. As illustrated in FIG. 14 and FIG. 15, the semiconductor device according to the second embodiment is different from the semiconductor device according to the first embodiment in the configuration of the trench contact section 5 of the active edge termination section 103.

The trench contact section 5 illustrated in FIG. 14 and FIG. 15 has a lattice-shaped planar shape. The trench contact section 5 includes two stripe portions 51a, 51c extending in the first direction (the up-down direction in FIG. 14), and a plurality of connecting portions 52a provided between the stripe portions 51a, 51c and extending in the second direction (the right-left direction in FIG. 14) perpendicular to the first direction. One end, in the second direction, of each of the plurality of connecting portions 52a is connected to the stripe portion 51a, and the other end, in the second direction, of each of the plurality of connecting portions 52a is connected to the stripe portion 51c. The length L1 of the plurality of connecting portions 52a in the second direction is longer than the length L1 of the plurality of connecting portions 52a illustrated in FIG. 6. The other configuration of the semiconductor device according to the second embodiment is similar to that of the semiconductor device according to the first embodiment, and therefore, a redundant description thereof is omitted.

In the semiconductor device according to the second embodiment, the trench contact section 5 of the active edge termination section 103 is configured such that the stripe portions 51a, 51c extending in the first direction are connected to each other via the plurality of connecting portions 52a. Accordingly, the extraction amount of carriers is increased in the outer side surface and the bottom surface of the outermost stripe portion 51a, the bottom surface and two side surfaces facing each other in the first direction in each of the plurality of connecting portions 52a connected to the stripe portion 51a, and so on, so that carriers can be extracted equally. This makes it possible to increase a contact area effective to equally extract carriers, thereby making it possible to improve a tolerance.

### Third Embodiment

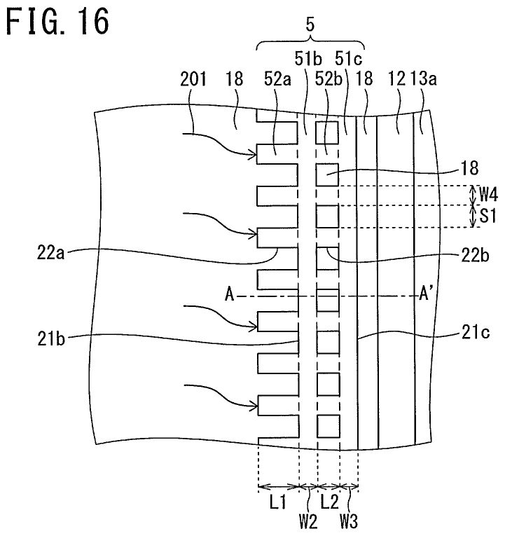

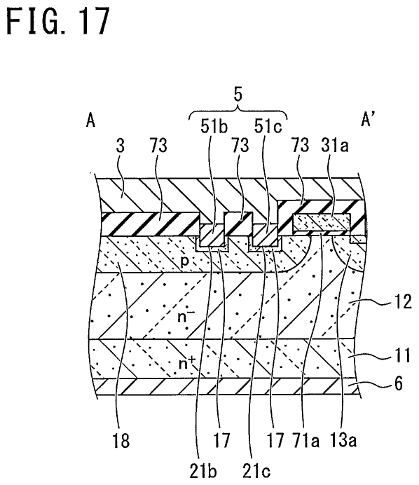

FIG. 16 is a plan view of a part of a semiconductor device according to a third embodiment and corresponds to the plan view of the semiconductor device according to the first embodiment illustrated in FIG. 6. FIG. 17 is a sectional view taken along a line A-A′ in FIG. 16. As illustrated in FIG. 16 and FIG. 17, the semiconductor device according to the third embodiment is different from the semiconductor device according to the first embodiment in the configuration of the trench contact section 5 of the active edge termination section 103.

The trench contact section 5 illustrated in FIG. 16 and FIG. 17 includes two stripe portions 51b, 51c extending in the first direction (the up-down direction in FIG. 16), the plurality of connecting portions 52a provided outwardly from the stripe portion 51b and extending in the second direction (the right-left direction in FIG. 16) perpendicular to the first direction, and a plurality of connecting portions 52b provided between the stripe portions 51b, 51c. One end, in the second direction, of each of the plurality of connecting portions 52a is connected to the stripe portion 51b. One end, in the second direction, of each of the plurality of connecting portions 52b is connected to the stripe portion 51b, and the other end, in the second direction, of each of the plurality of connecting portions 52b is connected to the stripe portion 51c. The length L1 of the plurality of connecting portions 52a in the second direction is longer than the length L2 of the plurality of connecting portions 52b. The other configuration of the semiconductor device according to the third embodiment is similar to that of the semiconductor device according to the first embodiment, and therefore, a redundant description thereof is omitted.

In the semiconductor device according to the third embodiment, the trench contact section 5 of the active edge termination section 103 is configured such that the plurality of connecting portions 52a is connected to the stripe portion 51b, and the stripe portions 51b, 51c are connected to each other via the plurality of connecting portions 52b. Hereby, the extraction amount of carriers is increased in the outer side surface, in the second direction, of each of the plurality of outermost connecting portions 52a, the bottom surface thereof, and two side surfaces thereof facing each other in the first direction, the outer side surface and the bottom surface of the stripe portion 51b connected to the plurality of connecting portions 52a, and so on, so that carriers can be extracted equally. This makes it possible to increase a contact area effective to equally extract carriers, thereby making it possible to improve a tolerance.

### Fourth Embodiment

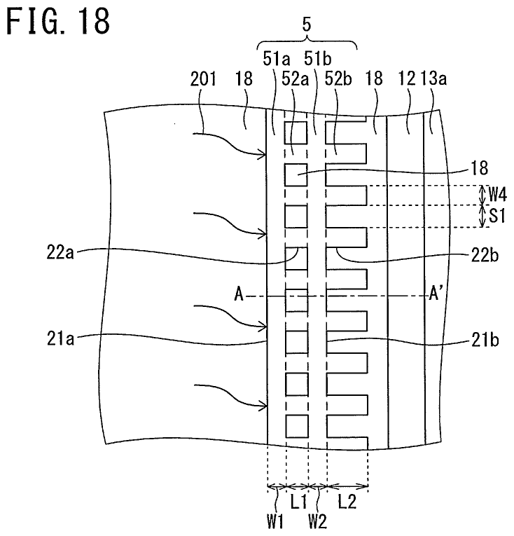

FIG. 18 is a plan view of a part of a semiconductor device according to a fourth embodiment and corresponds to the plan view of the semiconductor device according to the first embodiment illustrated in FIG. 6. As illustrated in FIG. 18, the semiconductor device according to the fourth embodiment is different from the semiconductor device according to the first embodiment in the configuration of the trench contact section 5 of the active edge termination section 103.

The trench contact section 5 illustrated in FIG. 18 has a structure obtained by horizontally reversing the trench contact section 5 of the semiconductor device according to the third embodiment illustrated in FIG. 16. The trench contact section 5 includes two stripe portions 51a, 51b extending in the first direction (the up-down direction in FIG. 18), a plurality of connecting portions 52a provided between the stripe portions 51a, 51b, and a plurality of connecting portions 52b provided inwardly from the stripe portion 51b and extending in the second direction (the right-left direction in FIG. 18) perpendicular to the first direction. One end, in the second direction, of each of the plurality of connecting portions 52a is connected to the stripe portion 51a, and the other end, in the second direction, of each of the plurality of connecting portion 52a is connected to the stripe portion 51b. One end, in the second direction, of each of the plurality of connecting portions 52b is connected to the stripe portion 51b. The length L2 of the plurality of connecting portions 52b in the second direction is longer than the length L1 of the plurality of connecting portions 52a. The other configuration of the semiconductor device according to the fourth embodiment is similar to that of the semiconductor device according to the first embodiment, and therefore, a redundant description thereof is omitted.

In the semiconductor device according to the fourth embodiment, the trench contact section 5 of the active edge termination section 103 is configured such that the stripe portions 51a, 51b are connected to each other via the plurality of connecting portions 52a, and the plurality of connecting portions 52b is connected to the stripe portion 51b. Hereby, the extraction amount of carriers is increased in the outer side surface and the bottom surface of the outermost stripe portion 51a, the bottom surface and two side surfaces facing each other in the first direction in each of the plurality of connecting portions 52a connected to the stripe portion 51a, and so on, so that carriers can be extracted equally. This makes it possible to increase a contact area effective to equally extract carriers, thereby making it possible to improve a tolerance.

### Fifth Embodiment

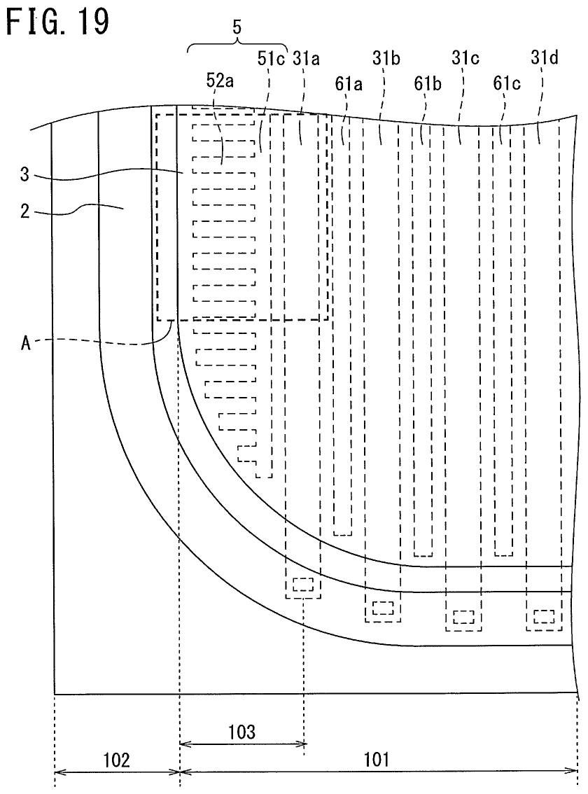

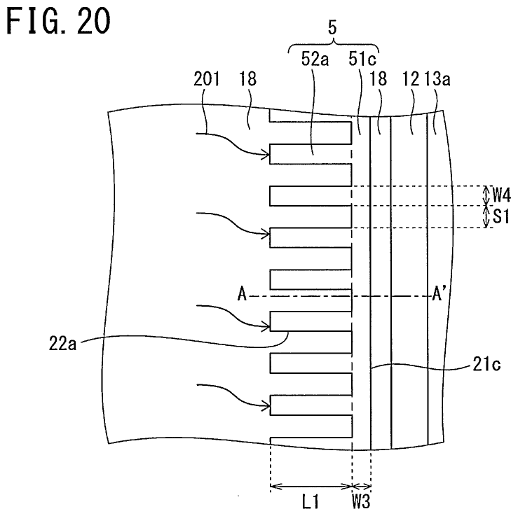

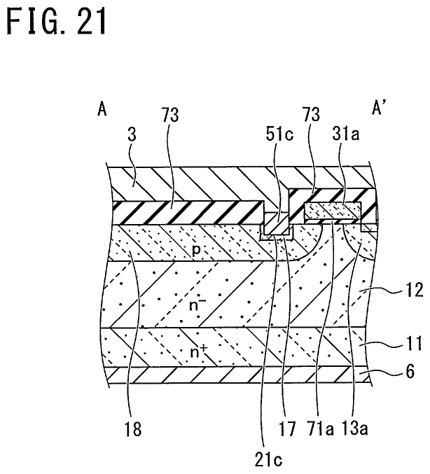

FIG. 19 is a plan view of a part of a semiconductor device according to a fifth embodiment and corresponds to the plan view of the semiconductor device according to the first embodiment illustrated in FIG. 2. FIG. 20 is a plan view illustrating a region A in FIG. 19 in an enlarged manner. FIG. 21 is a sectional view taken along a line A-A′ in FIG. 20. As illustrated in FIG. 19 to FIG. 21, the semiconductor device according to the fifth embodiment is different from the semiconductor device according to the first embodiment in the configuration of the trench contact section 5 of the active edge termination section 103.

The trench contact section 5 illustrated in FIG. 19 to FIG. 21 has a comb-shaped planar shape. The trench contact section 5 includes one stripe portion 51c extending in the first direction (the up-down direction in FIG. 20), and a plurality of connecting portions 52a provided outwardly from the stripe portion 51c and extending in the second direction (the right-left direction in FIG. 20) perpendicular to the first direction. The stripe portion 51c corresponds to a handgrip portion of the comb-shape, and the plurality of connecting portions 52a corresponds to tooth portions of the comb-shape. One end, in the second direction, of each of the plurality of connecting portions 52a is connected to the stripe portion 51c. The length L1 of the plurality of connecting portions 52a in the second direction is longer than the length L1 of the plurality of connecting portions 52a illustrated in FIG. 6.

As illustrated in FIG. 19, the source electrode 3 has a curved shape in a rectangular corner (corner portion) in the planar shape of the active area 101. The length, in the second direction (the right-left direction in FIG. 19), of the plurality of connecting portions 52a included in the trench contact section 5 of the active edge termination section 103 varies along the curved shape of the corner of the active area 101 and becomes shorter toward the corner of the active area 101. The other configuration of the semiconductor device according to the fifth embodiment is similar to that of the semiconductor device according to the first embodiment, and therefore, a redundant description thereof is omitted.

In the semiconductor device according to the fifth embodiment, the trench contact section 5 of the active edge termination section 103 is configured such that the plurality of connecting portions 52a is connected to the outer side of the stripe portion 51c. Hereby, the extraction amount of carriers is increased in the outer side surface in the second direction, the bottom surface, and two side surfaces facing each other in the first direction in each of the outermost connecting portions 52a, the outer side surface and the bottom surface of the stripe portion 51b connected to the plurality of connecting portions 52a, and so on, so that carriers can be extracted equally. This makes it possible to increase a contact area effective to equally extract carriers, thereby making it possible to improve a tolerance.

Furthermore, in the semiconductor device according to the fifth embodiment, the length, in the second direction, of the plurality of connecting portions 52a included in the trench contact section 5 of the active edge termination section 103 varies along the curved shape of the corner of the active area 101 in the corner (corner portion) of the rectangular shape of the planar shape of the active area 101. Accordingly, carriers are easily equally extracted even from the corner of the active area 101.

### Sixth Embodiment

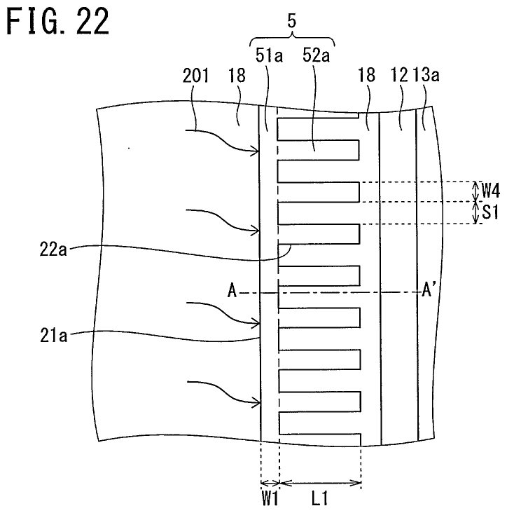

FIG. 22 is a plan view of a part of a semiconductor device according to a sixth embodiment and corresponds to the plan view of the semiconductor device according to the first embodiment illustrated in FIG. 6. As illustrated in FIG. 22, the semiconductor device according to the sixth embodiment is different from the semiconductor device according to the first embodiment in the configuration of the trench contact section 5.

The trench contact section 5 illustrated in FIG. 22 has a structure obtained by horizontally reversing the trench contact section 5 of the semiconductor device according to the fifth embodiment illustrated in FIG. 20. The trench contact section 5 includes one stripe portions 51a extending in the first direction (the up-down direction in FIG. 22), and the plurality of connecting portions 52a provided inwardly from the stripe portion 51a and extending in the second direction (the right-left direction in FIG. 22) perpendicular to the first direction. One end, in the second direction, of each of the plurality of connecting portions 52a is connected to the stripe portion 51a. The length L1 of the plurality of connecting portions 52a in the second direction is longer than the length L1 of the plurality of connecting portions 52a illustrated in FIG. 6. The other configuration of the semiconductor device according to the sixth embodiment is similar to that of the semiconductor device according to the first embodiment, and therefore, a redundant description thereof is omitted.

In the semiconductor device according to the sixth embodiment, the trench contact section 5 of the active edge termination section 103 is configured such that the plurality of connecting portions 52a is connected to the stripe portion 51a. Hereby, the extraction amount of carriers is increased in the outer side surface and the bottom surface of the outermost stripe portion 51a, the bottom surface and two side surfaces facing each other in the first direction in each of the plurality of connecting portions 52a connected to the stripe portion 51a, and so on, so that carriers can be extracted equally. This makes it possible to increase a contact area effective to equally extract carriers, thereby making it possible to improve a tolerance.

### Seventh Embodiment

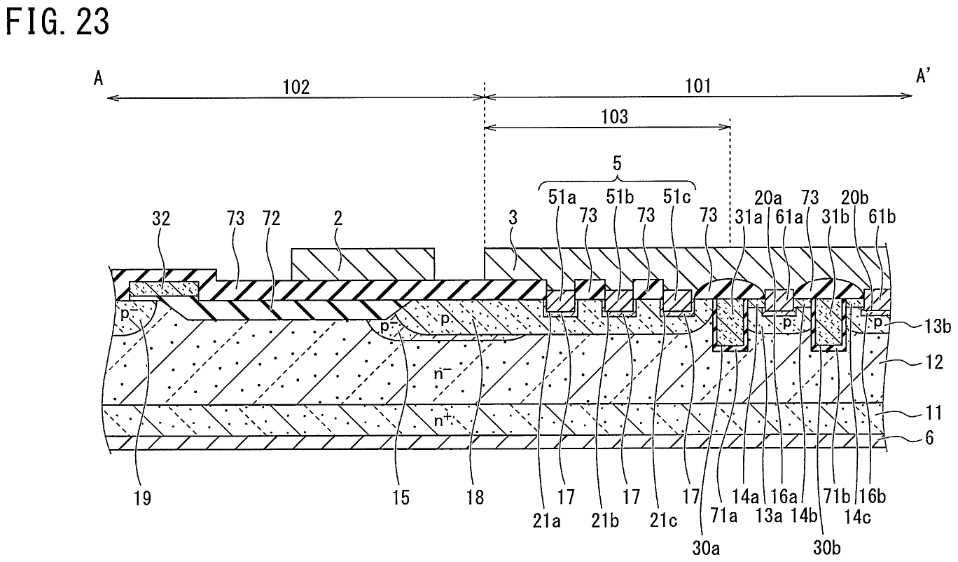

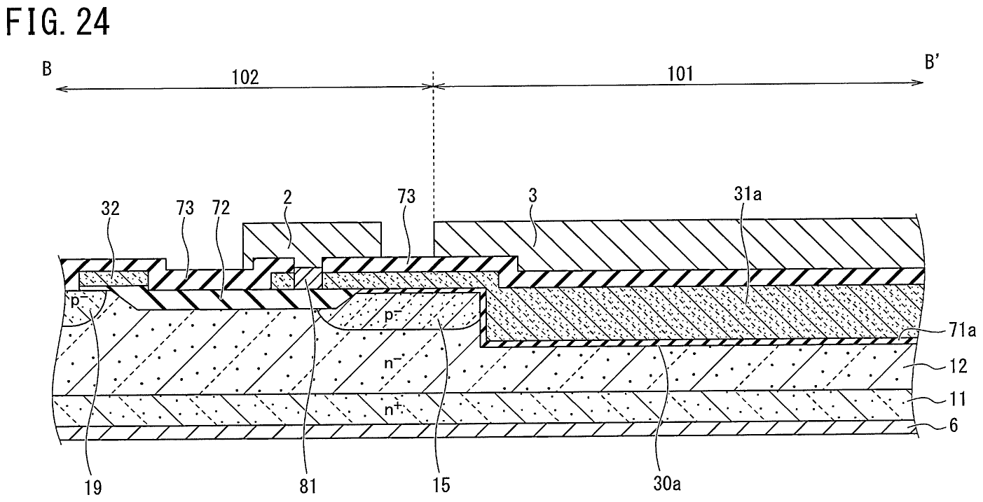

FIG. 23 is a sectional view of a part of a semiconductor device according to a seventh embodiment and corresponds to the sectional view of the part of the semiconductor device according to the first embodiment illustrated in FIG. 3. FIG. 24 is a sectional view of another part of the semiconductor device according to the seventh embodiment and corresponds to the sectional view of the part of the semiconductor device according to the first embodiment illustrated in FIG. 4. As illustrated in FIG. 23 and FIG. 24, the semiconductor device according to the seventh embodiment is different from the semiconductor device according to the first embodiment in that the active element in the active area 101 is a vertical MOSFET having a trench-gate structure.

A plurality of trenches (gate trenches) 30a, 30b are provided to be separated from each other and arranged in parallel to each other in an upper portion of the n⁻-type drift layer 12. An n⁺-type source region 14a and a p-type base region 13a make contact with a right side surface of the gate trench 30a. An n⁺-type source region 14b and the p-type base region 13a make contact with a left side surface of the gate trench 30b. An n⁺-type source region 14c and a side surface of a p-type base region 13b make contact with a right side surface of the gate trench 30b. Respective bottom portions of the gate trenches 30a, 30b make contact with the drift layer 12. The gate trenches 30a, 30b have linear (stripe-shaped) planar shapes extending in parallel to each other along a depth direction in FIG. 23 and the right-left direction in FIG. 24.

A mesa portion constituted by an upper portion of the drift layer 12 is provided between the gate trenches 30a, 30b adjacent to each other. The mesa portion is a region of the drift layer 12 which region is sandwiched between the gate trenches 30a, 30b adjacent to each other and is a region above the deepest position in the gate trenches 30a, 30b.

The gate insulating film 71a is provided to cover a bottom surface and side surfaces of the gate trench 30a. The gate electrode 31a is embedded in the gate trench 30a via the gate insulating film 71a. The insulated-gate electrode structure (31a, 71a) is constituted by the gate insulating film 71a and the gate electrode 31a. The gate insulating film 71b is provided to cover a bottom surface and side surfaces of the gate trench 30b. The gate electrode 31b is embedded in the gate trench 30b via the gate insulating film 71b. The insulated-gate electrode structure (31b, 71b) is constituted by the gate insulating film 71b and the gate electrode 31b.

The interlayer insulating film 73 is provided on top surfaces of the mesa portion of the drift layer 12 and the insulated-gate electrode structures (31a, 71a), (31b, 71b). The interlayer insulating film 73 provided on the mesa portion of the drift layer 12 has a contact hole passing through the interlayer insulating film 73. The mesa portion of the drift layer 12 includes the trenches (contact trenches) 20a, 20b continuous with the contact hole.

Side surfaces of the contact trench 20a make contact with the source regions 14a, 14b. A bottom portion of the contact trench 20a makes contact with the p⁺-type contact region 16a. The trench contact section (the plug section) 61a is embedded in the contact trench 20a. A side surface of the contact trench 20b makes contact with the source region 14c. A bottom portion of the contact trench 20b makes contact with the p⁺-type contact region 16b. The trench contact section (the plug section) 61b is embedded in the contact trench 20b.

The front-surface electrode (the source electrode) 3 is provided on the interlayer insulating film 73. The source electrode 3 is electrically connected to the source regions 14a to 14c and the contact regions 16a, 16b via the trench contact sections 61a, 61b.

The n⁺-type drain region 11 having an impurity concentration higher than that of the drift layer 12 is provided on the bottom surface side of the drift layer 12. The back-surface electrode (drain electrode) 6 is provided on the bottom surface of the drain region 11.

The other configuration of the semiconductor device according to the seventh embodiment, such as the voltage blocking area 102 and the active edge termination section 103, is similar to that of the semiconductor device according to the first embodiment, and a redundant description thereof is omitted.

With the semiconductor device according to the seventh embodiment, even in a case where the active element in the active area 101 is a vertical MOSFET having a trench gate structure, it is possible to increase a contact area effective to equally extract carriers in the active edge termination section 103, similarly to the semiconductor device according to the first embodiment, thereby making it possible to improve a tolerance. Note that, as the trench contact section 5 of the active edge termination section 103 in the semiconductor device according to the seventh embodiment, a configuration similar to that of the trench contact section 5 of the active edge termination section 103 in the semiconductor device according to any of the first to sixth embodiments can be employed.

### Eighth Embodiment

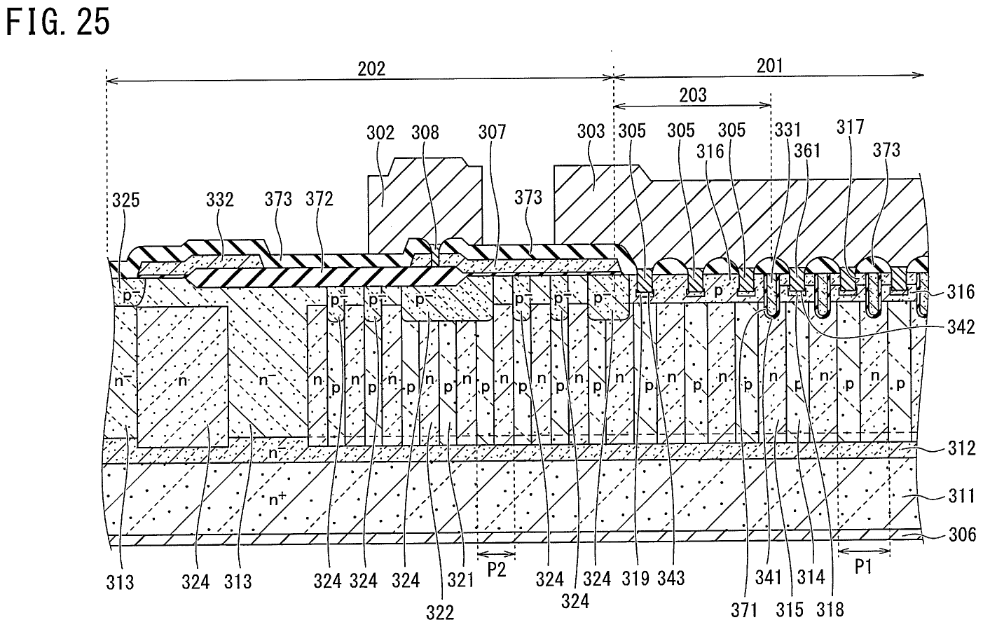

FIG. 25 is a sectional view of a part of a semiconductor device according to an eighth embodiment and corresponds to the sectional view of the part of the semiconductor device according to the first embodiment illustrated in FIG. 3. As illustrated in FIG. 25, the semiconductor device according to the eighth embodiment is different from the semiconductor device according to the first embodiment in that an active element in an active area 201 is a MOSFET having a superjunction (SJ) structure.

The semiconductor device according to the eighth embodiment includes the active area 201, and a voltage blocking area 202 provided outwardly from the active area 201 to surround the active area 201. An active edge termination section 203 is provided in an edge section on the voltage blocking area 202 side of the active area 201.

The semiconductor device according to the eighth embodiment includes an n⁺-type semiconductor substrate 311, a drain electrode 306 provided on the bottom surface side of the semiconductor substrate 311, an n⁻-type buffer layer 312 provided on the top surface side of the semiconductor substrate 311 and having an impurity concentration lower than that of the semiconductor substrate 311, and an n-type drift layer 313 provided on the top surface side of the buffer layer 312 and having an impurity concentration lower than that of the buffer layer 312.

In the active area 201, a p-type semiconductor region (p-type column) 314 and an n-type semiconductor region (n-type column) 315 are provided alternately and periodically on the top surface side of the buffer layer 312. The p-type column 314 and the n-type column 315 have a sectional shape extending in the up-down direction in FIG. 25. The p-type column 314 and the n-type column 315 have a planar shape extending in the depth direction in FIG. 25. A p-type base region 316 is provided on the top surface sides of the p-type column 314 and the n-type column 315. An n⁺-type source region 317 is provided on the top surface side of the base region 316.

A trench (gate trench) 341 is provided in the depth direction from a top surface of the source region 317. A lower end of the gate trench 341 reaches the n-type column 315. A gate insulating film 371 and a gate electrode 331 are embedded in the gate trench 341. An interlayer insulating film 373 is provided on the top surface side of the gate electrode 331. A source electrode 303 is provided on the top surface side of the interlayer insulating film 373.

A trench (contact trench) 342 is provided in the depth direction from the top surface of the source region 317, at a position continuous with a contact hole provided in the interlayer insulating film 373. A lower end of the contact trench 342 reaches the n-type column 315. A p⁺-type contact region 318 is provided in a bottom portion of the contact trench 342. A trench contact section (a plug section) 361 is embedded in the contact trench 342. The source region 317 is electrically connected to the source electrode 303 via the trench contact section 361.

At the time when the semiconductor device according to the eighth embodiment is turned off, depletion layers extend laterally in the p-type column 314 and the n-type column 315 from a p-n junction between the p-type column 314 and the n-type column 315, and the depletion layers are easily connected, thereby making it possible to achieve a high breakdown voltage.

In the active edge termination section 203, a trench (contact trench) 343 is provided in the depth direction from a top surface of the base region 316. A p⁺-type contact region 319 is provided in a bottom portion of the contact trench 343. A trench contact section (a plug section) 305 is embedded in the contact trench 343. The trench contact section 305 is provided above the p-type column 314. The trench contact section 305 has a configuration similar to that of the trench contact section 5 in the semiconductor device according to the first embodiment, and a redundant description thereof is omitted.

In the voltage blocking area 202, a p-type semiconductor region (p-type column) 321 and an n-type semiconductor region (n-type column) 322 are provided alternately and periodically on the top surface side of the buffer layer 312. A repetition pitch P2 of the p-type column 321 and the n-type column 322 in the voltage blocking area 202 is smaller than a repetition pitch P1 of the p-type column 314 and the n-type column 315 in the active area 201.

A plurality of p⁻-type semiconductor regions (resurf regions) 324 is provided on the top surface sides of the p-type column 321 and the n-type column 322. A gate wiring line 307 made of polysilicon is provided on the top surface sides of the resurf regions 324 via a field insulating film 372. A gate runner 302 is provided on the top surface side of the gate wiring line 307 via the interlayer insulating film 373. The gate runner 302 is electrically connected to the gate wiring line 307 via a trench contact section 308 embedded in a contact hole provided in the interlayer insulating film 373.

An n-type column 323 is provided outwardly from the p-type column 321 and the n-type column 322 via the drift layer 313. A p-type semiconductor region (channel stopper) 325 is provided in a chip edge portion that is an outermost periphery of the voltage blocking area 202. A field plate 332 made of polysilicon is provided on the top surface side of the channel stopper 325 via the field insulating film 372 made of a local insulating film (LOCOS film) or the like. The other configuration of the semiconductor device according to the eighth embodiment is similar to that of the semiconductor device according to the first embodiment, and therefore, a redundant description thereof is omitted.

With the semiconductor device according to the eighth embodiment, even in a case where the active element in the active area 201 is an MOSFET having an SJ structure, it is possible to increase a contact area effective to equally extract carriers in the active edge termination section 203, similarly to the semiconductor device according to the first embodiment, thereby making it possible to improve a tolerance. Note that, as the trench contact section 305 of the active edge termination section 203 in the semiconductor device according to the eighth embodiment, a configuration similar to that of the trench contact section 5 of the active edge termination section 103 in the semiconductor device according to any of the first to sixth embodiments can be employed.

### Ninth Embodiment

A semiconductor device according to a ninth embodiment has a configuration similar to the configuration of the semiconductor device according to the first embodiment. The ninth embodiment will describe the impurity concentration (dose) and the positional relationship of the contact region 17 and the contact regions 16a, 16b as p⁺-type highly-concentrated low resistance regions illustrated in FIG. 3.

As illustrated in FIG. 3, the active edge termination section 103 with a large amount of a reverse recovery current has a diode structure to restrain a parasitic bipolar junction transistor (BJT) operation, and the p⁺-type contact region 17 is formed to reduce a voltage to be generated by the reverse recovery current. The p⁺-type contact region 16a, 16b similar to the p⁺-type contact region 17 is also formed in a cell section in the active area 101, so that a parasitic BJT operation is restrained, avalanche resistance is improved, and a reduction in forward voltage is also achieved. At this time, conventionally, in order to reduce the resistance as much as possible, the impurity concentrations in the contact region 17 and the contact region 16a, 16b are increased, or respective distances d1, d2 of the contact region 17 and the contact region 16a, 16b to a p-n junction are shortened.

However, by forming the contact region 17 and the contact region 16a, 16b, a peak value (Irp) of the reverse recovery current increases and a reverse recovery tolerance decreases. In addition, due to a decrease in resistance, the rate of change (dIr/dt) of the reverse recovery current increases, a dielectric breakdown voltage (BVds) at the time of reverse recovery jumps up, and an electric field increases. Further, carrier inflow from the contact region 17 and the contact region 16a, 16b increases, and the amount of carriers near the p-n junction at the time of reverse recovery is large. This causes an increase in electric field, a decrease in avalanche voltage, concentration of an avalanche electric current, and a decrease in tolerance. In a case where the distances d1, d2 from the contact region 17 and the contact region 16a, 16b to a p-n junction are shortened to decrease a resistance, a high-resistance region of the diode shortens, the electric field increases, the avalanche voltage decreases, the avalanche electric current concentrates, and the tolerance decreases.

In view of this, in the semiconductor device according to the ninth embodiment, the dose of a p-type impurity such as boron (B) at the time of ion implantation to form the contact region 17 and the contact region 16a, 16b is set to about 5×10¹⁴ cm⁻² or more but 3×10¹⁵ cm⁻² or less, for example. When the dose in the contact region 17 and the contact region 16a, 16b is 5×10¹⁴ cm⁻² or more, it is possible to effectively restrain the parasitic BJT operation. In the meantime, when the dose in the contact region 17 and the contact region 16a, 16b is 3×10¹⁵ cm⁻² or less to restrain an excessive decrease in carrier extraction resistance at the time of reverse recovery, it is possible to restrain the peak value (Irp) of the reverse recovery current or the rate of change (dlr/dt) of current at the time when the reverse recovery current recovers from the peak value (Irp), thereby making it possible to improve the reverse recovery tolerance.

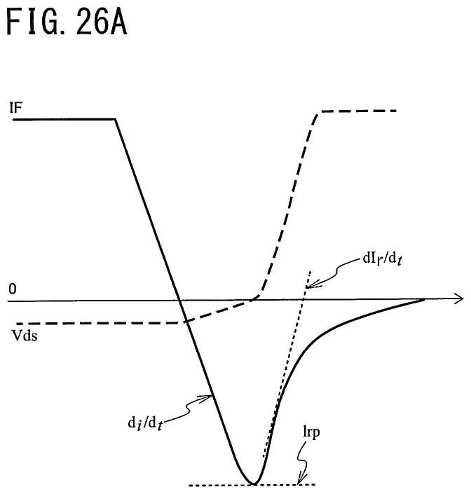

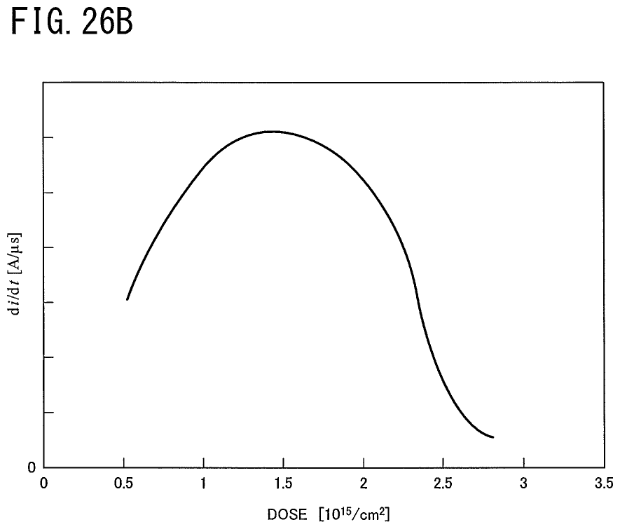

FIG. 26A illustrates reverse recovery properties of a forward current (IF) and a source-drain voltage (Vds) in a diode. As illustrated in FIG. 26A, the rate of change (dIr/dt) of current at the time when the reverse recovery current recovers from the peak value (Irp) indicates an inclination of time until the peak value (Irp) of the reverse recovery current generated in the examination on a reverse recovery tolerance reaches zero. Note that, when the rate of change (dlr/dt) of current increases at the time when the reverse recovery current recovers from the peak value (Irp), the source-drain voltage (Vds) increases sharply, so that a switching loss increases, and a tolerance easily decreases.

FIG. 26B is a graph illustrating the relationship between the dose in the contact region 17 and the contact region 16a, 16b and a rate of change (di/dt) of the reverse recovery current. As illustrated in FIG. 26B, from the viewpoint of increasing the rate of change (di/dt) of the reverse recovery current, the dose in the contact region 17 and the contact region 16a, 16b is preferably about 5×10¹⁴ cm⁻² or more but 2.5×10¹⁵ cm⁻² or less, more preferably about 5×10¹⁴ cm⁻² or more but 2×10¹⁵ cm⁻² or less, and furthermore preferably about 1×10¹⁵ cm⁻² or more but 2×10¹⁵ cm⁻² or less.

Here, the rate of change (di/dt) of the reverse recovery current indicates a condition for performing an examination on the reverse recovery tolerance. Further, the viewpoint of increasing the rate of change (di/dt) of the reverse recovery current is to decrease a switching loss. Note that, when the rate of change (di/dt) of the reverse recovery current increases, the peak value (Irp) of the reverse recovery current increases, so that the tolerance easily decreases. In view of this, a condition under which the tolerance does not decrease even if the examination is performed with a large rate of change (di/dt) of the reverse recovery current is selected.

The dose of a p-type impurity such as boron (B) at the time of ion implantation to form the well region 18 and the base region 13a, 13b in contact with the contact region 17 and the contact region 16a, 16b, respectively, can be set appropriately based on static characteristics such as a breakdown voltage, an on-resistance (Ron), a gate threshold voltage (Vth), and a forward voltage (Vf) requested to each element, and a switching characteristic. The dose in the well region 18 and the base region 13a, 13b is, for example, 1×10¹³ cm⁻² or more but 2×10¹⁴ cm⁻² or less. When the dose in the well region 18 and the base region 13a, 13b is 1×10¹³ cm⁻² or more, it is possible to restrain a decrease in breakdown voltage, to restrain a decrease in gate threshold voltage (Vth), to restrain a decrease in forward transconductance (gfs), to restrain an increase in forward voltage (Vf), to restrain a decrease in avalanche resistance, and to restrain a decrease in switching characteristic. In the meantime, when the dose in the well region 18 and the base region 13a, 13b is 2×10¹⁴ cm⁻² or less, it is possible to restrain a decrease in breakdown voltage, to restrain an increase in gate threshold voltage (Vth), to restrain an increase in on-resistance (Ron), to restrain a decrease in forward transconductance (gfs), to restrain a decrease in reverse recovery tolerance, and to restrain switching noise.

In a case where the semiconductor device according to the ninth embodiment has a low breakdown voltage, the dose in the well region 18 and the base region 13a, 13b may be about 1×10¹³ cm⁻² or more but 3×10¹³ cm⁻² or less. In a case where the semiconductor device according to the ninth embodiment has a middle or high breakdown voltage, no barrier metal film is provided in contact sections with the contact region 17 and the contact region 16a, 16b, and no electron beam is applied at the time of manufacturing the semiconductor device according to the ninth embodiment, the dose in the well region 18 and the base region 13a, 13b may be about 2×10¹³ cm⁻² or more but 4×10¹³ cm⁻² or less. In a case where the semiconductor device according to the ninth embodiment has a middle or high breakdown voltage, a barrier metal film is formed in contact sections with the contact region 17 and the contact region 16a, 16b, and an electron beam is applied at the time of manufacturing the semiconductor device according to the ninth embodiment, the dose in the well region 18 and the base region 13a, 13b may be about 4×10¹³ cm⁻² or more but 2×10¹⁴ cm⁻² or less.

The ratio of the dose in the contact region 17 to the dose in the well region 18 is about 5 times or more but 60 times or less, for example. When the ratio of the dose in the contact region 17 to the dose in the well region 18 is five times or more, it is possible to effectively restrain the parasitic BJT operation. In the meantime, when the ratio of the dose in the contact region 17 to the dose in the well region 18 is 60 times or less so as to restrain an excessive decrease in carrier extraction resistance at the time of reverse recovery, it is possible to improve the reverse recovery tolerance. The ratio of the dose in the contact region 16a, 16b to the dose in the base region 13a, 13b is generally the same as the ratio of the dose in the contact region 17 to the dose in the well region 18.

Further, in the semiconductor device according to the ninth embodiment, the distance d1 from the bottom surface of the contact region 17 to a p-n junction between the well region 18 and the drift layer 12 and the distance d2 from the contact region 16a, 16b to a p-n junction between the base region 13a, 13b and the drift layer 12 are set to about 0.5 μm or more but 2.0 μm or less, for example. When the distances d1, d2 from the contact region 17 and the contact region 16a, 16b to respective p-n junctions are set to 0.5 μm or more, it is possible to prevent depletion layers extending from the p-n junctions from reaching the contact region 17 and the contact region 16a, 16b, thereby making it possible to prevent the breakdown voltage from decreasing. Furthermore, it is possible to restrain excessive generation of carriers during reverse recovery, to relax an electric field in the well region 18 and the base region 13a, 13b, and to restrain a decrease in tolerance due to the decrease in breakdown voltage. In the meantime, when the distances d1, d2 from the contact region 17 and the contact region 16a, 16b to respective p-n junctions are set to 2.0 μm or less, it is possible to restrain a decrease in breakdown voltage, to restrain an increase in on-resistance (Ron), to restrain a decrease in forward transconductance (gfs), to restrain an increase in forward voltage (Vf), to restrain an increase in input capacitance (Ciss), and to restrain a decrease in feedback capacity (Crss).

The distances d1, d2 from the contact region 17 and the contact region 16a, 16b to respective p-n junctions can be set appropriately based on a characteristic such as a breakdown voltage class requested to an element, an ion-implantation accelerating voltage along with that, and so on. In a case of low-accelerating ion implantation (for example, about 50 keV) such as a case where the contact region 17 and the contact region 16a, 16b are formed in a bottom portion of a trench contact, the distances d1, d2 from the contact region 17 and the contact region 16a, 16b to respective p-n junctions are set to about 0.5 μm or more but 1.0 μm or less, for example. In a case of high-accelerating ion implantation (for example, about 120 keV) such as a case where the contact region 17 and the contact region 16a, 16b are formed on the top surface of a semiconductor substrate that is not a trench contact, the distances d1, d2 from the contact region 17 and the contact region 16a, 16b to respective p-n junctions are set to about 1.0 μm or more but 2.0 μm or less, for example. The other configuration of the semiconductor device according to the ninth embodiment is similar to that of the semiconductor device according to the first embodiment, and therefore, a redundant description thereof is omitted.

In the semiconductor device according to the ninth embodiment, the impurity concentration (dose) in the contact region 17 and the contact region 16a, 16b is set within a predetermined range, so that the reverse recovery current (Irp) or the rate of change (dIr/dt) of the reverse recovery current is restrained, thereby making it possible to improve the reverse recovery tolerance. Further, when the ratio of the dose in the contact region 17 to the dose in the well region 18 and the ratio of the dose in the contact region 16a, 16b to the dose in the base region 13a, 13b are set within a predetermined range, it is possible to improve the reverse recovery tolerance. In addition, when the distances d1, d2 from the contact region 17 and the contact region 16a, 16b to respective p-n junctions are set within a predetermined range, it is possible to improve the reverse recovery tolerance. Note that, not only the configuration of the semiconductor device according to the first embodiment but the configurations of the semiconductor devices according to the second to eighth embodiments can yield similar effects.

### Tenth Embodiment

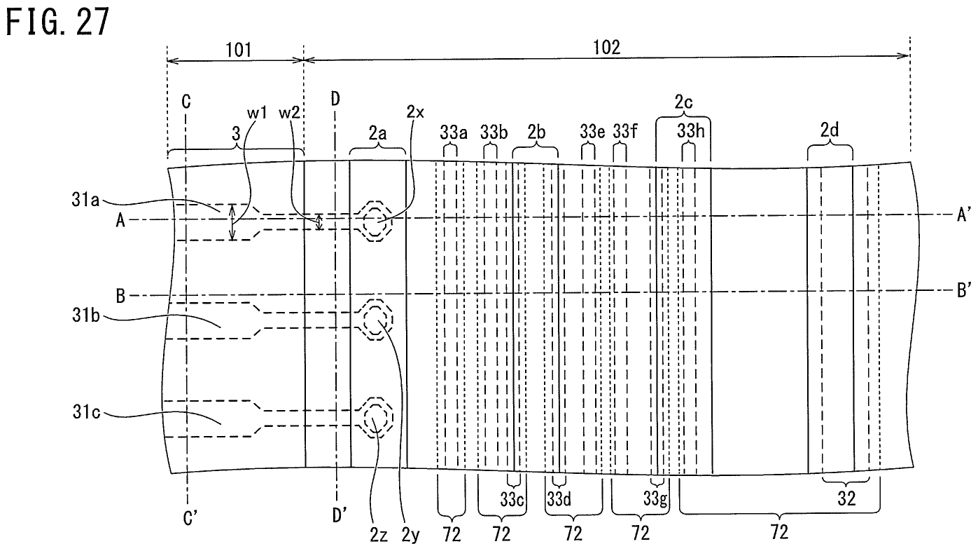

FIG. 27 is a plan view of a part of a semiconductor device according to a tenth embodiment. In FIG. 27, for convenience, the source electrode 3, gate wiring lines 2a to 2c, and a field plate 2d are illustrated with a continuous line, gate electrodes 31a to 31c and field plates 33a to 33h are illustrated with a broken line, and the field insulating film 72 is illustrated with a dotted line. The semiconductor device according to the tenth embodiment includes the active area 101, and the voltage blocking area 102 provided outwardly from the active area 101. In FIG. 27, the position of an edge portion of the source electrode 3 is at the position of a boundary between the active area 101 and the voltage blocking area 102.

The gate electrodes 31a to 31c of the active element included in the active area 101 extend in a stripe shape in the first direction (the right-left direction in FIG. 27) and are separated from each other in the second direction (the up-down direction in FIG. 27) perpendicular to the first direction. The gate electrodes 31a to 31c extend from the active area 101 to the voltage blocking area 102. Respective edge portions of the gate electrodes 31a to 31c in the first direction are connected to the gate wiring line 2a at contact sections 2x, 2y, 2z, respectively. The gate electrodes 31a to 31c have a width w1 on the active area 101 side. The gate electrodes 31a to 31c have a width w2 smaller than the width w1 from the vicinity of the boundary between the active area 101 and the voltage blocking area 102 to the contact sections 2x, 2y, 2z with the gate wiring line 2a.

In the voltage blocking area 102, the gate wiring lines 2a to 2c made of metal and the field plate 2d made of metal are separated from each other in the first direction (the right-left direction in FIG. 27) and extend in a stripe shape in the second direction (the up-down direction in FIG. 27). A plurality of field insulating films 72 is separated from each other in the first direction (the right-left direction in FIG. 27) and extends in a stripe shape in the second direction (the up-down direction in FIG. 27). A plurality of field plates 33a to 33h made of polysilicon is separated from each other in the first direction (the right-left direction in FIG. 27) and extends in a stripe shape in the second direction (the up-down direction in FIG. 27).

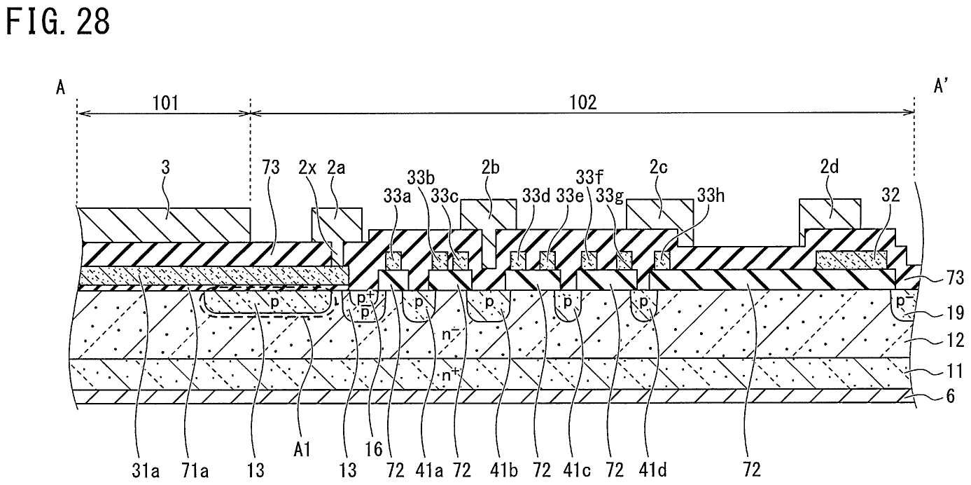

FIG. 28 is a sectional view taken along a line A-A′ passing through the gate electrode 31a illustrated in FIG. 27. As illustrated in FIG. 28, two p-type well regions 13 are provided on the active area 101 side on the top surface side of the n-type drift layer 12 such that the two p-type well regions 13 are separated from each other. A well region 13 on the inner side (the left side in FIG. 28) out of the two p-type well regions 13 is placed right under a portion of the gate electrode 31a illustrated in FIG. 27 which portion has the small width w2. The depth of a well region 13 on an outer side (the right side in FIG. 28) is deeper than the depth of the well region 13 on the inner side. The p⁺-type contact region 16 having an impurity concentration higher than that of the well region 13 is provided at the position of an edge portion of the gate electrode 31a, on the top surface side of the well region 13 on the outer side. The contact region 16 is provided to surround the gate electrodes 31a to 31c illustrated in FIG. 27. Further, p-type resurf regions 41a to 41d are provided outwardly from the well region 13 on the outer side. The p⁻-type channel stopper 19 is provided in a chip edge portion on the top surface side of the drift layer 12.

The gate electrode 31a made of polysilicon or the like is provided on the top surface of the drift layer 12 on the active area 101 side, via the gate insulating film 71a. The field plates 33a to 33h, 32 made of polysilicon or the like are provided on the top surface of the drift layer 12 on the voltage blocking area 102 side, via the field insulating film 72. The field insulating film 72 has openings exposing respective top surfaces of the contact region 16, the resurf regions 41a to 41d, and the channel stopper 19. The field insulating film 72, the gate electrode 31a, and the field plates 33a to 33h, 32 are coated with the interlayer insulating film 73. The source electrode 3 and the gate wiring line 2a are provided above the gate electrode 31a via the interlayer insulating film 73. The gate wiring line 2a is connected to the edge portion of the gate electrode 31a via the contact section 2x. The gate wiring lines 2b, 2c are provided above the field plates 33a to 33h via the interlayer insulating film 73. The field plate 2d is provided above the field plate 32 via the interlayer insulating film 73.

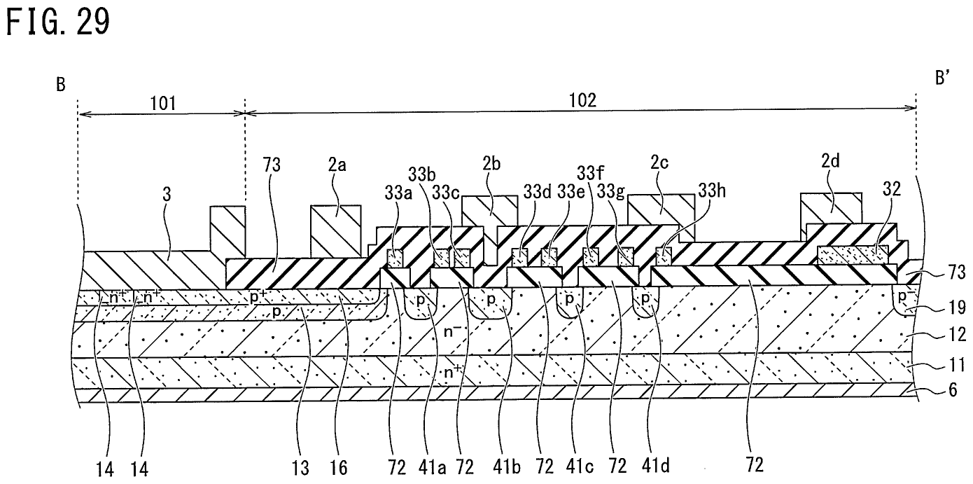

FIG. 29 is a sectional view taken along a line B-B′ passing between the gate electrodes 31a, 31b illustrated in FIG. 27. In FIG. 29, the p-type well region 13 is provided on the top surface side of the n″-type drift layer 12. The well region 13 is provided to extend from the active area 101 to the voltage blocking area 102. The p⁺-type contact region 16 is provided on the top surface side of the well region 13. The contact region 16 is provided to extend from the active area 101 to the voltage blocking area 102. An n⁺-type source region 14 is provided on a part of the top surface side of the contact region 16. Respective top surfaces of the contact region 16 and the source region 14 make contact with the source electrode 3.

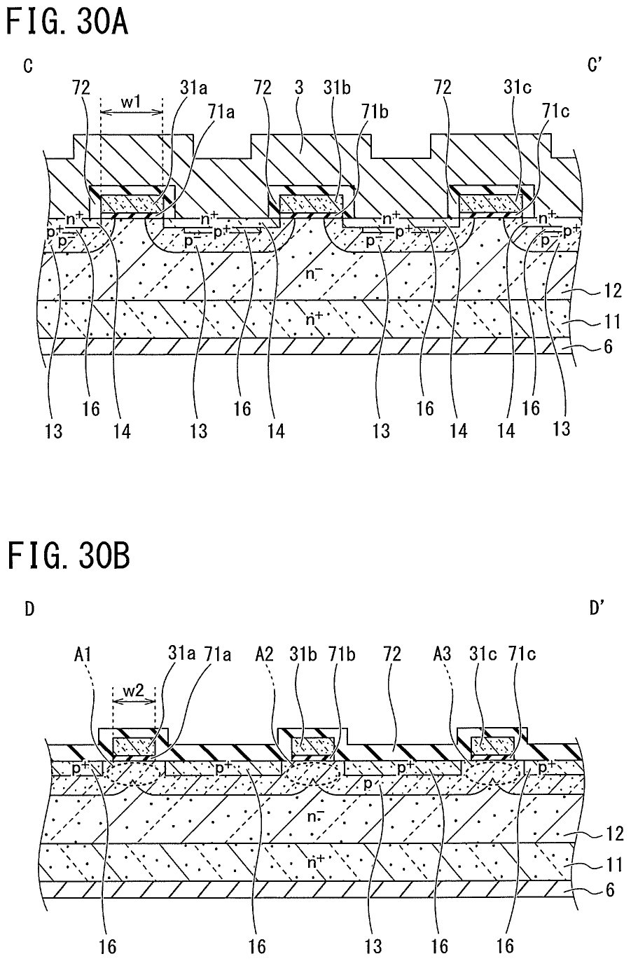

FIG. 30A is a sectional view taken along a line C-C′ passing through respective portions of the gate electrodes 31a to 31c illustrated in FIG. 27 which portions have the large width w1. As illustrated in FIG. 30A, a plurality of p-type well regions 13 is provided on the top surface side of the n⁻-type drift layer 12 such that the plurality of p-type well regions 13 is separated from each other. The well region 13 functions as a base region (a channel formation region) for the active element. The p⁺-type contact region 16 and the n⁺-type source region 14 are provided on the top surface side of the well region 13.

FIG. 30B is a sectional view taken along a line D-D′ passing through respective portions of the gate electrodes 31a to 31c illustrated in FIG. 27 which portions have the small width w2. As illustrated in FIG. 30B, the p-type well region 13 is provided on the top surface side of the drift layer 12. The well region 13 is divided into multiple regions at the position of FIG. 30A but is a connected region at the position of FIG. 30B. The depth of the well region 13 right under the gate electrodes 31a to 31c is shallower than the depth of the well region 13 placed between the gate electrodes 31a to 31c. Further, the impurity concentration in the well region 13 right under the gate electrodes 31a to 31c is lower than the impurity concentration in the well region 13 disposed between the gate electrodes 31a to 31c. In FIG. 28 and FIG. 30B, regions A1 to A3 where the well region 13 is relatively shallow in depth and the impurity concentration is low are schematically illustrated with a broken line.

As illustrated in FIG. 30B, the plurality of p⁺-type contact regions 16 is provided on the top surface side of the well region 13 such that the plurality of p⁺-type contact regions 16 is separated from each other. The contact region 16 is provided selectively in a region, between the gate electrodes 31a to 31c, where the well region 13 is deep in depth and the impurity concentration is high. No contact region 16 is provided in the regions A1 to A3, right under the gate electrodes 31a to 31c, where the well region 13 is shallow in depth and the impurity concentration is low. The other configuration of the semiconductor device according to the tenth embodiment is similar to that of the semiconductor device according to the first embodiment, and therefore, a redundant description thereof is omitted.

With the semiconductor device according to the tenth embodiment, in respective portions with the small width w2 in the gate electrodes 31a to 31c, the p⁺-type contact region 16 is provided to be separated from the regions A1 to A3 right under the gate electrodes 31a to 31c in which regions A1 to A3 the well region 13 is shallow in depth and the impurity concentration is low. Accordingly, it is possible to restrain excessive carrier injection, to prevent a further increase in electric field and a decrease in breakdown voltage, and to restrain a decrease in reverse recovery tolerance.

### Eleventh Embodiment

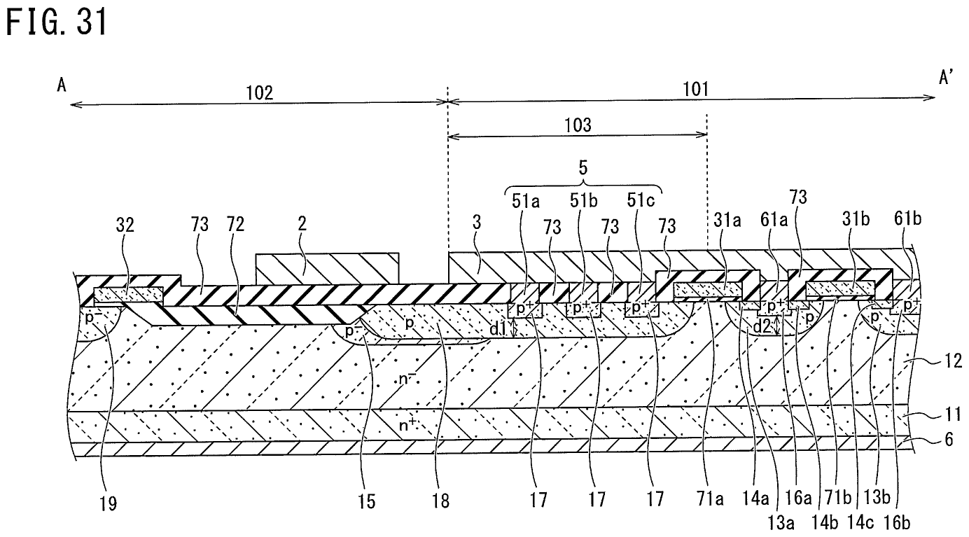

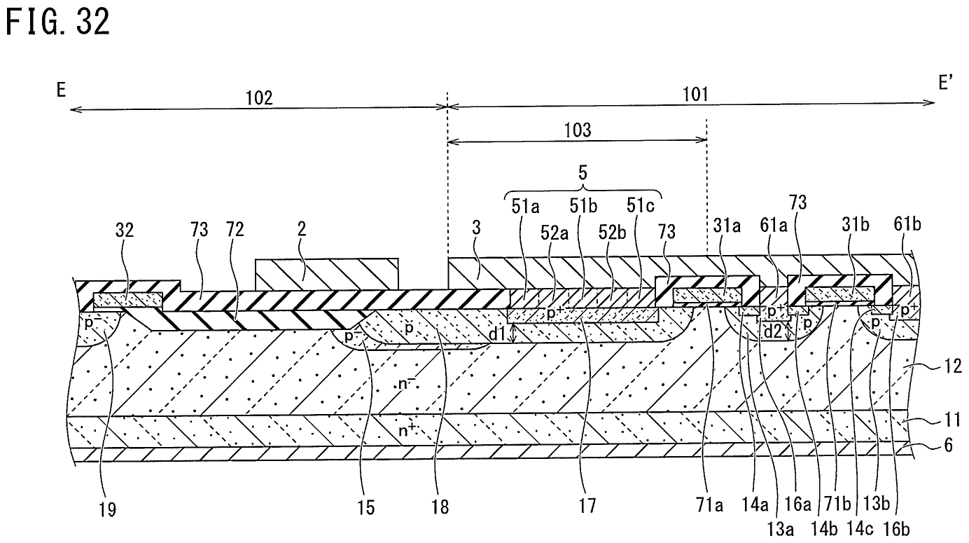

FIG. 31 is a sectional view of a part of a semiconductor device according to an eleventh embodiment and corresponds to the position of the section of the part of the semiconductor device according to the first embodiment illustrated in FIG. 3. FIG. 32 is a sectional view of another part of the semiconductor device according to the eleventh embodiment and corresponds to the position of a section taken along a line E-E′ in the plan view of the semiconductor device according to the first embodiment illustrated in FIG. 2.

As illustrated in FIG. 31 and FIG. 32, the semiconductor device according to the eleventh embodiment is different from the semiconductor device according to the first embodiment in that the contact sections 61a, 61b of the active element in the active area 101 and the contact section 5 of the active edge termination section 103 are normal contact sections (planar contact sections) not embedded in trenches.

Respective side surfaces of the contact sections 61a, 61b of the active element in the active area 101 make contact with the interlayer insulating film 73. A bottom surface of the contact section 61a makes contact with respective top surfaces of the source regions 14a, 14b and the contact region 16a. A bottom surface of the contact section 61b makes contact with respective top surfaces of the source region 14c and the contact region 16b.

The contact section 5 of the active edge termination section 103 includes the plurality of (three) stripe portions 51a to 51c, the plurality of connecting portions 52a provided between the stripe portions 51a, 51b and separated from each other in the first direction, and the plurality of connecting portions 52b provided between the stripe portions 51b, 51c and separated from each other in the first direction. Respective side surfaces of the stripe portions 51a to 51c and the connecting portions 52a, 52b make contact with the interlayer insulating film 73. Respective bottom surfaces of the stripe portions 51a to 51c and the connecting portions 52a, 52b make contact with the contact regions 17. The other configuration of the semiconductor device according to the eleventh embodiment is similar to that of the semiconductor device according to the first embodiment, and therefore, a redundant description thereof is omitted.

In the semiconductor device according to the eleventh embodiment, the contact sections 61a, 61b of the active element in the active area 101 and the contact section 5 of the active edge termination section 103 may be normal contact sections not embedded in trenches. Even in this case, similarly to the semiconductor device according to the first embodiment, it is possible to increase a contact area effective to equally extract carriers by the contact section 5 in the active edge termination section 103, thereby making it possible to improve a tolerance.

Further, similarly to the semiconductor device according to the tenth embodiment, the impurity concentration (dose) in the contact region 17 and the contact region 16a, 16b is set within a predetermined range, so that the reverse recovery current (Irp) or the rate of change (dlr/dt) in the reverse recovery current is restrained, thereby making it possible to improve the reverse recovery tolerance. Further, when the ratio of the dose in the contact region 17 to the dose in the well region 18 and the ratio of the dose in the contact region 16a, 16b to the dose in the base region 13a, 13b are set within a predetermined range, it is possible to improve the reverse recovery tolerance. In addition, when the distances d1, d2 from the contact region 17 and the contact region 16a, 16b to respective p-n junctions are set within a predetermined range, it is possible to improve the reverse recovery tolerance. Note that semiconductor devices according to twelfth to seventeenth embodiments described below also yield similar effects.

### Twelfth Embodiment

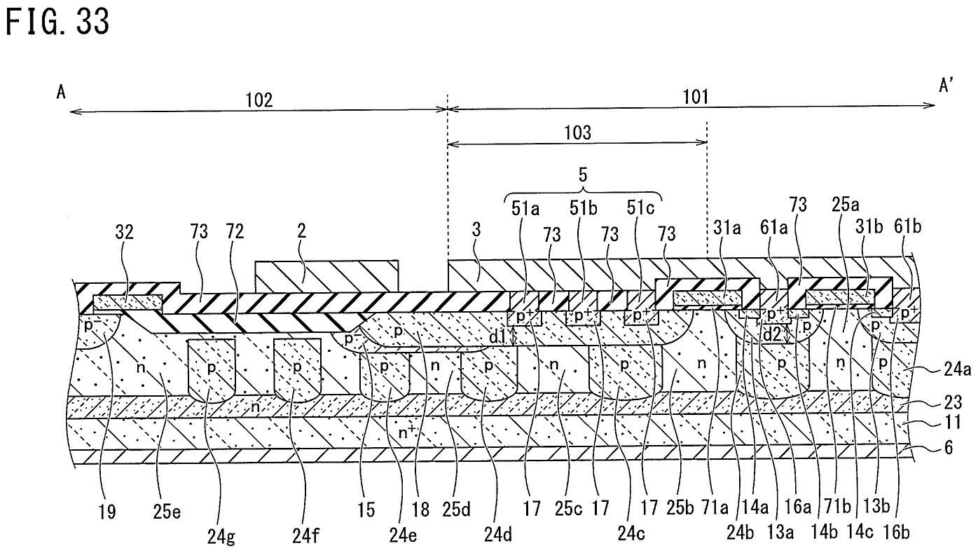

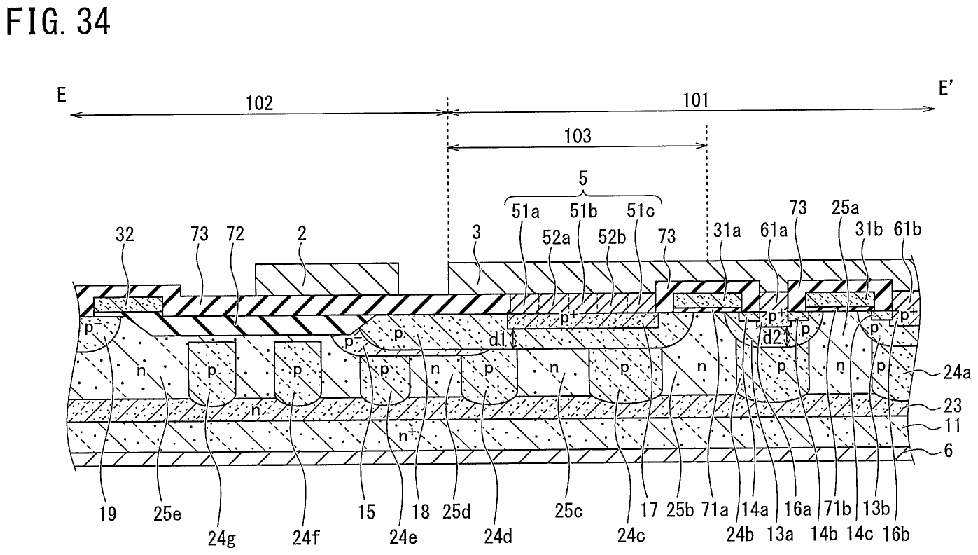

FIG. 33 is a sectional view of a part of a semiconductor device according to a twelfth embodiment and corresponds to the position of the section of the part of the semiconductor device according to the eleventh embodiment illustrated in FIG. 31. FIG. 34 is a sectional view of another part of the semiconductor device according to the twelfth embodiment and corresponds to the position of the section of the part of the semiconductor device according to the eleventh embodiment illustrated in FIG. 32.

As illustrated in FIG. 33 and FIG. 34, the semiconductor device according to the twelfth embodiment is different from the semiconductor device according to the eleventh embodiment illustrated in FIGS. 31, 32 in that the active element in the active area 101 is a MOSFET having a superjunction (SJ) structure.

An n-type buffer region 23 is provided on the top surface side of the drain region 11. In the active area 101, p-type semiconductor regions (p-type columns) 24a to 24d and n-type semiconductor regions (n-type columns) 25a to 25d are provided alternately and periodically on the top surface side of the buffer region 23. A top surface of the p-type column 24a makes contact with the base region 13b. A top surface of the p-type column 24b makes contact with the base region 13a. A top surface of the p-type column 24c makes contact with the well region 18. A top surface of the p-type column 24d makes contact with the well region 18 and the resurf region 15.

In the voltage blocking area 102, p-type semiconductor regions (p-type columns) 24e to 24g are provided on the top surface side of the buffer region 23 such that the p-type semiconductor regions (p-type columns) 24e to 24g are separated from each other, and an n-type semiconductor region 25e is provided to be sandwiched between the p-type columns 24e to 24g. A top surface of the p-type column 24e makes contact with the resurf region 15. Respective top surfaces of the p-type columns 24f, 24g are separated from the field insulating film 72 via the n-type semiconductor region 25e. The other configuration of the semiconductor device according to the twelfth embodiment is similar to that of the semiconductor device according to the eleventh embodiment, and therefore, a redundant description thereof is omitted.

With the semiconductor device according to the twelfth embodiment, the active element in the active area 101 may be a MOSFET having an SJ structure. Even in this case, it is possible to increase a contact area effective to equally extract carriers by the contact section 5 in the active edge termination section 103, thereby making it possible to improve a tolerance.

### Thirteenth Embodiment

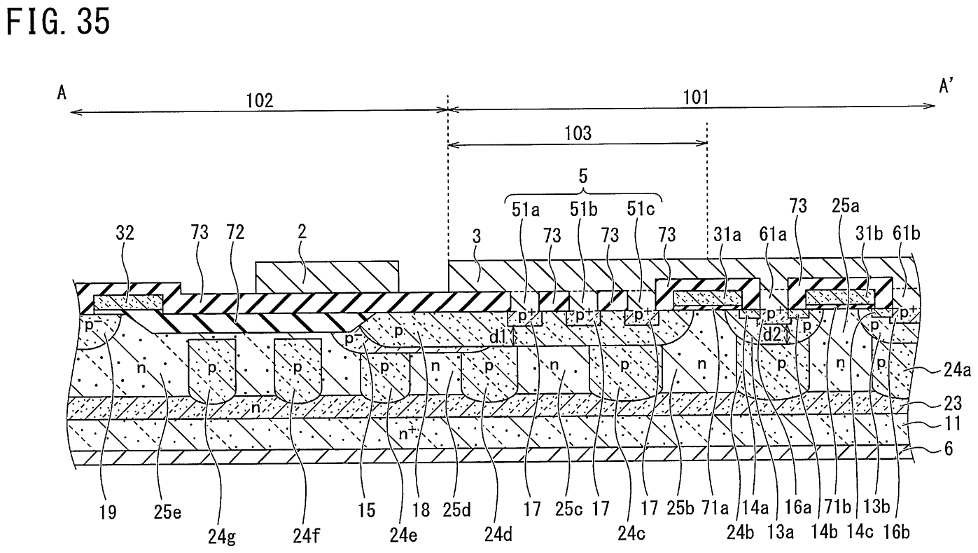

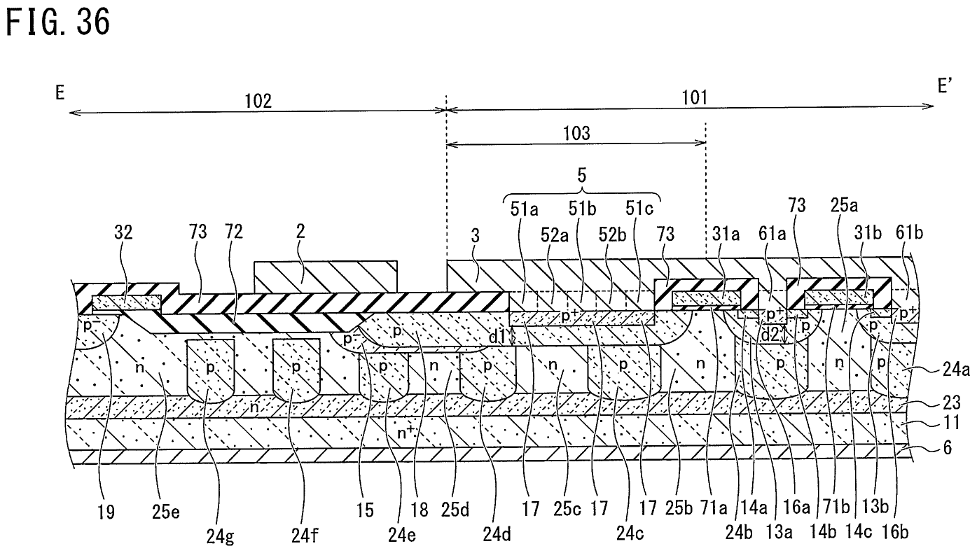

FIG. 35 is a sectional view of a part of a semiconductor device according to a thirteenth embodiment and corresponds to the position of the section of the part of the semiconductor device according to the twelfth embodiment illustrated in FIG. 33. FIG. 36 is a sectional view of a part of the semiconductor device according to the thirteenth embodiment and corresponds to the position of the section of the part of the semiconductor device according to the twelfth embodiment illustrated in FIG. 34.

As illustrated in FIG. 35 and FIG. 36, the semiconductor device according to the thirteenth embodiment is different from the semiconductor device according to the twelfth embodiment illustrated in FIG. 33 and FIG. 34 in that the contact sections 61a, 61b of the active element in the active area 101 and the contact section 5 of the active edge termination section 103 are provided integrally with the source electrode 3.

The contact sections 61a, 61b of the active element in the active area 101 and the contact section 5 of the active edge termination section 103 are made of a metal material such as aluminum, which is the same as the source electrode 3. The other configuration of the semiconductor device according to the thirteenth embodiment is similar to that of the semiconductor device according to the twelfth embodiment, and therefore, a redundant description thereof is omitted.

With the semiconductor device according to the thirteenth embodiment, the contact sections 61a, 61b of the active element in the active area 101 and the contact section 5 of the active edge termination section 103 may be provided integrally with the source electrode 3. Even in this case, it is possible to increase a contact area effective to equally extract carriers by the contact section 5 in the active edge termination section 103, thereby making it possible to improve a tolerance.

### Fourteenth Embodiment

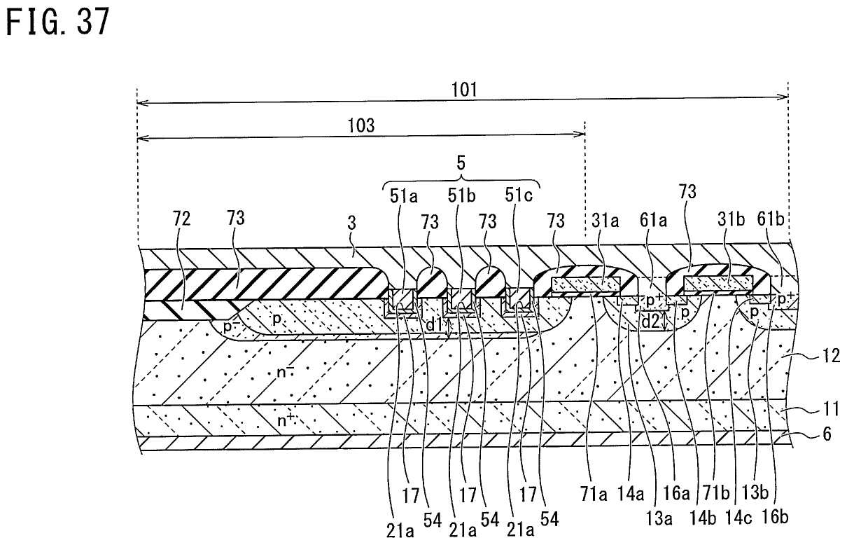

FIG. 37 is a sectional view of a part of a semiconductor device according to a fourteenth embodiment and corresponds to a position on the active edge termination section 103 side in the section of the part of the semiconductor device according to the first embodiment illustrated in FIG. 3. As illustrated in FIG. 37, the semiconductor device according to the fourteenth embodiment is the same as the semiconductor device according to the first embodiment illustrated in FIG. 3 in that the contact section 5 of the active edge termination section 103 is constituted by trench contact sections embedded in the trenches 21a to 21c, but the semiconductor device according to the fourteenth embodiment is different from the semiconductor device according to the first embodiment illustrated in FIG. 3 in that the contact sections 61a, 61b of the active element in the active area 101 are normal contact sections not embedded in trenches.

The contact sections 61a, 61b of the active element in the active area 101 are provided integrally with the source electrode 3. The contact section 5 of the active edge termination section 103 includes the plurality of (three) stripe portions 51a to 51c embedded in respective trenches 21a to 21c via barrier metal films 54. The other configuration of the semiconductor device according to the fourteenth embodiment is similar to that of the semiconductor device according to the first embodiment, and therefore, a redundant description thereof is omitted.

With the semiconductor device according to the fourteenth embodiment, the contact sections 61a, 61b of the active element in the active area 101 may be normal contact sections not embedded in trenches, and the contact section 5 of the active edge termination section 103 may be constituted by trench contact sections embedded in the trenches 21a to 21c. Even in this case, it is possible to increase a contact area effective to equally extract carriers by the contact section 5 in the active edge termination section 103, thereby making it possible to improve a tolerance.

### Fifteenth Embodiment

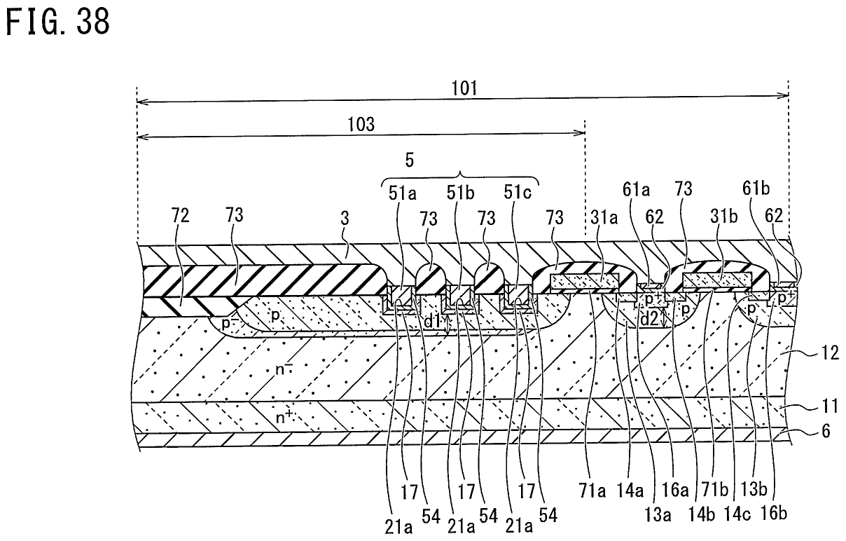

FIG. 38 is a sectional view of a part of a semiconductor device according to a fifteenth embodiment and corresponds to the position of the section of the part of the semiconductor device according to the fourteenth embodiment illustrated in FIG. 37. As illustrated in FIG. 38, the semiconductor device according to the fifteenth embodiment is different from the semiconductor device according to the fourteenth embodiment illustrated in FIG. 37 in that the contact sections 61a, 61b of the active element in the active area 101 are plug sections provided separately from the source electrode 3.

The contact sections 61a, 61b of the active element in the active area 101 are made of metal such as tungsten (W). The contact section 61a is provided on the top surface sides of the contact region 16a and the source regions 14a, 14b via a barrier metal film 62. The contact section 61b is provided on the top surface sides of the contact region 16b and the source region 14c via the barrier metal film 62. The other configuration of the semiconductor device according to the fifteenth embodiment illustrated in FIG. 38 is similar to that of the semiconductor device according to the fourteenth embodiment illustrated in FIG. 37, and therefore, a redundant description thereof is omitted.

With the semiconductor device according to the fifteenth embodiment, the contact sections 61a, 61b of the active element in the active area 101 may be provided separately from the source electrode 3. Even in this case, it is possible to increase a contact area effective to equally extract carriers by the contact section 5 in the active edge termination section 103, thereby making it possible to improve a tolerance.

### Sixteenth Embodiment

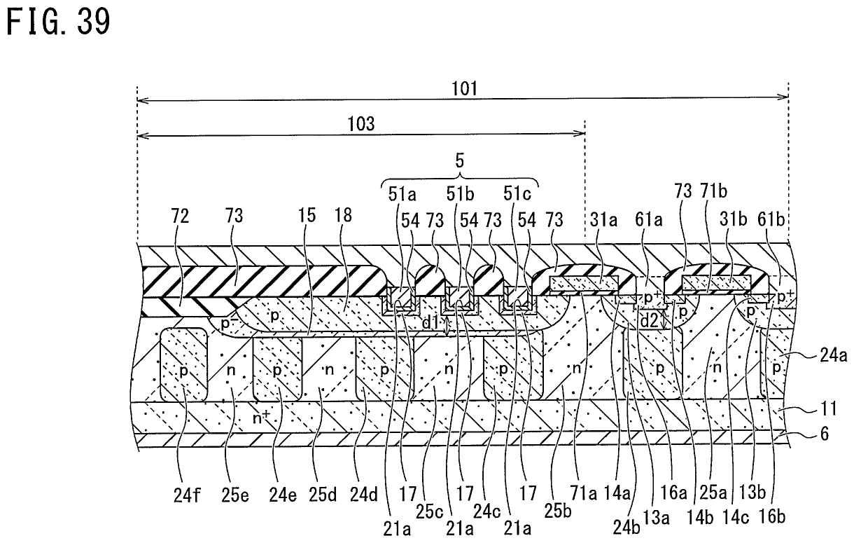

FIG. 39 is a sectional view of a part of a semiconductor device according to a sixteenth embodiment and corresponds to the position of the section of the part of the semiconductor device according to the fourteenth embodiment illustrated in FIG. 37. As illustrated in FIG. 39, the semiconductor device according to the sixteenth embodiment is different from the semiconductor device according to the fourteenth embodiment illustrated in FIG. 37 in that the active element in the active area 101 is a MOSFET having a superjunction (SJ) structure.

The p-type columns 24a to 24f and the n-type columns 25a to 25d are provided alternately on the top surface side of the drain region 11. The top surface of the p-type column 24a makes contact with the base region 13b. The top surface of the p-type column 24b makes contact with the base region 13a. The top surface of the p-type column 24c makes contact with the well region 18 and the resurf region 15. Respective top surfaces of the p-type columns 24d, 24e make contact with the resurf region 15. The top surface of the p-type column 24f is separated from the field insulating film 72 via the n-type semiconductor region 25e. The other configuration of the semiconductor device according to the sixteenth embodiment is similar to that of the semiconductor device according to the fourteenth embodiment illustrated in FIG. 37, and therefore, a redundant description thereof is omitted.

With the semiconductor device according to the sixteenth embodiment, the active element in the active area 101 may be a MOSFET having an SJ structure. Even in this case, it is possible to increase a contact area effective to equally extract carriers by the contact section 5 in the active edge termination section 103, thereby making it possible to improve a tolerance.

### Seventeenth Embodiment

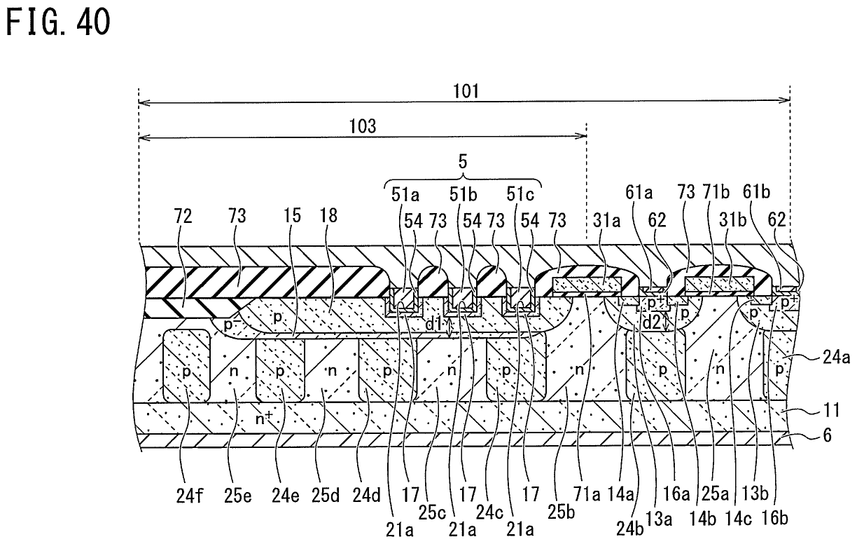

FIG. 40 is a sectional view of a part of a semiconductor device according to a seventeenth embodiment and corresponds to the position of the section of the part of the semiconductor device according to the fifteenth embodiment illustrated in FIG. 38. As illustrated in FIG. 40, the semiconductor device according to the seventeenth embodiment is different from the semiconductor device according to the fifteenth embodiment illustrated in FIG. 38 in that the active element in the active area 101 is a MOSFET having a superjunction (SJ) structure. The SJ structure is similar to that of the semiconductor device according to the sixteenth embodiment illustrated in FIG. 39, and therefore, a redundant description thereof is omitted. The other configuration of the semiconductor device according to the seventeenth embodiment is similar to that of the semiconductor device according to the fifteenth embodiment illustrated in FIG. 38, and therefore, a redundant description thereof is omitted.

With the semiconductor device according to the seventeenth embodiment, the active element in the active area 101 may be a MOSFET having an SJ structure. Even in this case, it is possible to increase a contact area effective to equally extract carriers by the contact section 5 in the active edge termination section 103, thereby making it possible to improve a tolerance.

### Other Embodiments

As described above, the present disclosure has been described according to the first to seventeenth embodiments, but it should not be understood that the description and drawings implementing a portion of this disclosure limit the present disclosure. Various alternative embodiments of the present disclosure, examples, and operational techniques will be apparent to those skilled in the art from this disclosure.

For example, the MOSFET is described as the semiconductor devices according to the first to seventeenth embodiments, but the present disclosure is also applicable to an insulated gate bipolar transistor (IGBT) configured such that a p⁺-type collector region is substituted for the n⁺-type drain region of the MOSFET. As the IGBT, a single IGBT, a reverse conductive IGBT (RC-IGBT), or a reverse blocking insulated gate bipolar transistor (RB-IGBT) is also usable.

Further, the semiconductor devices according to the first to seventeenth embodiments deal with a case where the contact section 5 includes one to three stripe portions 51a to 51c, but the contact section 5 may include four or more stripe portions. A plurality of connecting portions may not be necessarily connected to a stripe portion other than an outermost stripe portion.

The configurations disclosed in the first to seventeenth embodiments may be combined as appropriate within a range that does not contradict with the scope of the respective embodiments. As described above, the present disclosure includes various embodiments of the present disclosure and the like not described herein. Therefore, the scope of the present disclosure is defined only by the technical features specifying the present disclosure, which are prescribed by claims, the words and terms in the claims shall be reasonably construed from the subject matters recited in the present specification.

What is claimed is:

1. A semiconductor device including an active area and a voltage blocking area provided outwardly from the active area, the semiconductor device comprising:
a semiconductor layer having a first conductivity type and provided over the active area and the voltage blocking area;
a first semiconductor region having a second conductivity type and provided on a top surface side of the semiconductor layer, in an edge section on the voltage blocking area side of the active area; and
a contact section provided on a top surface side of the first semiconductor region,
wherein the contact section includes:
a first stripe portion extending in a first direction along the edge section on the voltage blocking area side of the active area in a plan view; and
a plurality of first connecting portions connected to the first stripe portion and separated from each other in the first direction.

2. The semiconductor device according to claim 1, wherein the plurality of first connecting portions is provided inwardly from the first stripe portion.

3. The semiconductor device according to claim 1, wherein the plurality of first connecting portions is provided outwardly from the first stripe portion.

4. The semiconductor device according to claim 2, further comprising a second stripe portion provided inwardly from the first stripe portion in such a manner as to be separated from the first stripe portion, the second stripe portion being connected to the plurality of first connecting portions and extending in the first direction.

5. The semiconductor device according to claim 4, further comprising a plurality of second connecting portions provided inwardly from the second stripe portion, connected to the second stripe portion, and separated from each other in the first direction.

6. The semiconductor device according to claim 5, further comprising a third stripe portion provided inwardly from the second stripe portion in such a manner as to be separated from the second stripe portion, the third stripe portion being connected to the plurality of second connecting portions and extending in the first direction.

7. The semiconductor device according to claim 4, further comprising a plurality of second connecting portions provided outwardly from the first stripe portion, connected to the first stripe portion, and separated from each other in the first direction.

8. The semiconductor device according to claim 6, wherein:
the active area includes a corner having a curved shape in the plan view; and
the first to third stripe portions have respective lengths in the first direction which lengths vary along the curved shape.

9. The semiconductor device according to claim 8, wherein the contact section further includes a plurality of third connecting portions provided outwardly from the second stripe portion, connected to the second stripe portion, and varying in length in a second direction along the curved shape, the second direction being perpendicular to the first direction.

10. The semiconductor device according to claim 3, wherein:
the active area includes a corner having a curved shape in the plan view; and
the plurality of first connecting portions varies in length in a second direction along the curved shape, the second direction being perpendicular to the first direction.

11. The semiconductor device according to claim 1, wherein the active area includes an active element including a gate electrode extending in the first direction.

12. The semiconductor device according to claim 1, wherein the active area includes an active element having a planar gate structure.

13. The semiconductor device according to claim 1, wherein the active area includes an active element having a trench-gate structure.

14. The semiconductor device according to claim 1, wherein the active area includes an active element having a superjunction structure.

15. The semiconductor device according to claim 1, wherein the contact section is electrically connected to a front-surface electrode of an active element included in the active area.

16. The semiconductor device according to claim 1, wherein the contact section includes a barrier metal film and a contact plug.

17. The semiconductor device according to claim 16, wherein the contact plug includes refractory metal.

18. The semiconductor device according to claim 1, wherein the contact section is at least partially embedded in a trench provided on the top surface side of the first semiconductor region.

19. The semiconductor device according to claim 1, wherein the contact section is provided on a top surface of the first semiconductor region.

20. The semiconductor device according to claim 1, further comprising a contact region having a second conductivity type, provided on the top surface side of the first semiconductor region in contact with the contact section, and having an impurity concentration higher than an impurity concentration of the first semiconductor region.

21. The semiconductor device according to claim 20, wherein the contact region has a dose of 5×10¹⁴ cm⁻² or more but 3×10¹⁵ cm⁻² or less.

22. The semiconductor device according to claim 20, wherein a ratio of the dose in the contact region to a dose in the first semiconductor region is 5 times or more but 60 time or less.

23. The semiconductor device according to claim 20, wherein a distance of the contact region to a p-n junction between the semiconductor layer and the first semiconductor region is 0.5 μm or more.

24. The semiconductor device according to claim 1, wherein:
the active area includes an active element including a plurality of gate electrodes separated from each other and extending in the first direction; and
the semiconductor device further includes:
a second semiconductor region having a second conductivity type, provided on the top surface side of the semiconductor layer, and shallower in depth at positions overlapping with edge portions of the plurality of gate electrodes in the first direction than at a position overlapping with a portion between the edge portions of the plurality of gate electrodes, and
a third semiconductor region having a second conductivity type, provided on a top surface side of a deep-depth portion of the second semiconductor region in such a manner as to be separated from a shallow-depth portion of the second semiconductor region, and having an impurity concentration higher than an impurity concentration of the second semiconductor region.
